(19) United States
(12) Patent Application Publication
(10) Pub. No.: US 2014/0198420 A1
(43) Pub. Date: Jul. 17, 2014

(54) Fault-Likely Detector

(71) Applicant: Ljubomir A. Kojovic, Racine, WI (US)

(72) Inventor: Ljubomir A. Kojovic, Racine, WI (US)

(73) Assignee: COOPER TECHNOLOGIES COMPANY, Houston, TX (US)

(21) Appl. No.: 13/739,237

(22) Filed: Jan. 11, 2013

(51) Int. Cl. G01R 31/08; H02H 3/20

(52) U.S. Cl. CPC G01R 31/08; H02H 3/20
USPC 361/86; 324/522

(57) ABSTRACT

A method, device, and system for detecting a fault for a protective device. The device can receive an input signal and detect a power spike in the input signal. If a power spike is detected in the input signal, the device simultaneously disables the trip mechanism for one or more protective devices and starts a time period. During the remainder of the time period, the device compares the input signal and the threshold value. If, during the remainder of the time period, the input signal exceeds the threshold value, and if the fault originates within a region between the multiple sensing devices, then the trip mechanism for each protective device is again enabled.

### TECHNICAL FIELD

The present disclosure relates generally to relay protection and more particularly to systems, methods, and devices for mitigating erroneous relay operation caused by power spikes.

### BACKGROUND

Switching of high-voltage electric apparatus (such as circuit breakers) can generate high-frequency voltage and/or current excursions, also called “spikes” or “bursts”. These excursions can penetrate through instrument transformers and the corresponding secondary wiring to protective device inputs, distorting the relay input signals. While many protective devices filter higher frequencies, the distorted relay input signals caused by power excursions cannot be entirely eliminated. As such, the power excursions can penetrate through the relay filters as one or multiple power spikes superimposed on the measured signal. As a result, distorted relay input signals can cause erroneous operation of the protective device. This phenomenon can especially be a problem for fast-operating protective devices, such as differential relays.

### SUMMARY

In general, in one aspect, the disclosure relates to a method for detecting a likely fault for a protective device. The method can include receiving an input signal, and detecting a power spike of the input signal. The method can also include, upon detecting the power spike, disabling a trip mechanism, disabling a complementary trip mechanism of a complementary protective device, and starting a time period. The method can further include, during a remainder of the time period, determining, using the complementary protective device, whether the power spike originated between the sensing device and the complementary sensing device, and determining whether the input signal exceeds the threshold value.

In another aspect, the disclosure can generally relate to a protection device. The protection device can include memory for storing instructions, and a hardware processor communicably coupled to the memory, where the hardware processor executes the instructions stored in the memory. The protection device can also include a trip mechanism that sends a trip signal to a breaker. The protection device can also include a correlation filter that detects a power spike in an input signal, and a timer that measures a time period. The protection device can further include a protection engine communicably coupled to the timer, a first sensing device, a second sensing device, the trip mechanism, the correlation filter, and the hardware processor. The protection engine can receive the input signal generated by the first sensing device. The protection engine can also, upon detection of the power spike, disable the trip mechanism, disable a complimentary trip mechanism of a complementary protective device, and instruct the timer to start measuring the time period. The protection engine can further, during a remainder of the time period, determine, using the complementary protective device, whether the power spike originated between the sensing device and the complementary sensing device, and determine whether the input signal exceeds the threshold value. The protection engine can enable and activate the trip mechanism and the complementary trip mechanism when the input signal exceeds the threshold value during the remainder of the time period.

In another aspect, the disclosure can generally relate to a protective device system. The protective device system can include at least one electrical component, and a first sensing device coupled to a first conductor, where the first sensing device generates an input signal based on power flowing through the first conductor. The protective device system can also include a protective device communicably coupled to the first sensing device and the second sensing device. The protective device can include memory for storing instructions, and a hardware processor communicably coupled to the memory, where the hardware processor executes the instructions stored in the memory. The protective device can also include a trip mechanism that sends a trip signal to the at least one electrical component. The protective device can also include a correlation filter that detects a power spike in the input signal, and a timer that measures a time period. The protective device can further include a protection engine communicably coupled to the timer, the first sensing device, and the hardware processor. The protection engine can receive the input signal generated by the first sensing device. The protection engine can also, upon detection of the power spike, disable the trip mechanism, disable a complementary trip mechanism of a complementary protective device, and instruct the timer to start measuring the time period. The protection engine can further, during a remainder of the time period, determine, using the complementary protective device, whether the power spike originated between the sensing device and the complementary sensing device, and determine whether the input signal exceeds the threshold value.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIG. 1 shows a protective device system using an example protective device in accordance with certain example embodiments.

FIG. 2 shows an example protective device in accordance with certain example embodiments.

FIG. 3A-C show various graphs of an input signal for an example protective device in accordance with certain example embodiments.

FIG. 4 shows a graph of an input signal that includes a spike and fault condition in accordance with certain example embodiments.

FIGS. 5A-D show various graphs of a raw and filtered input signal for each phase of an AC signal in accordance with certain example embodiments.

FIGS. 6A and 6B shows graphs of in-zone and out-of-zone faults in accordance with certain example embodiments.

FIG. 7 shows a flowchart of a method for mitigating the effect of a power spike on a protective device.

FIG. 8 shows a computer system used with an protective device in accordance with certain example embodiments.

FIGS. 9A-F show various graphs of an example of detecting a likely fault for an example protective device in accordance with certain example embodiments.

FIGS. 10A-F show various graphs of another example of detecting a likely fault for an example protective device in accordance with certain example embodiments.

FIGS. 11A-F show various graphs of yet another example of detecting a likely fault for an example protective device in accordance with certain example embodiments.

FIG. 12A shows a schematic flow diagram of an input signal through a protective device without the use of certain example embodiments.

FIG. 12B shows a schematic flow diagram of an input signal through a protective device with the use of certain example embodiments.

### DETAILED DESCRIPTION

Example embodiments of likely fault detection will now be described in detail with reference to the accompanying figures. Like, but not necessarily the same or identical, elements in the various figures are denoted by like reference numerals for consistency. In the following detailed description of the example embodiments, numerous specific details are set forth in order to provide a more thorough understanding of the disclosure herein. However, it will be apparent to one of ordinary skill in the art that the example embodiments herein may be practiced without these specific details. In other instances, well-known features have not been described in detail to avoid unnecessarily complicating the description. Further, certain descriptions (e.g., top, bottom, side, end, interior, inside, inner, outer) are merely intended to help clarify aspects of the invention and are not meant to limit embodiments described herein.

In general, example embodiments provide systems, methods, and devices for likely fault detection. Specifically, example embodiments provide for protective devices that determine whether a power spike is a lone excursion or the start of a fault before actuating. In such a case, the protective device strikes a balance between not actuating (generating a trip signal) when the input signal includes a mere, isolated power spike and not delaying actuation overly long when a legitimate fault is present in the circuit. As used herein, a power spike can also be called a power excursion. A fault can include one or more power spikes, which would occur at the beginning of a fault.

Example protective devices discussed herein can be used with and/or monitor one or more of a number of voltages and/or currents, which can also be described as various levels of power. For example, a protective device can monitor power devices that are electrically coupled to 345 kV alternating current (AC), where such power is operating power. As another example, the protective device can operate on 24 V direct current (DC), where such power is control power.

As used herein, the term “high-power” is used to describe higher amounts of power. Higher amounts of power, in terms of current, can be any current at or above approximately 100 Amperes (A), but can be less than 100 A in certain instances, as in a steady-state operating condition. High amounts of power can also be a voltage and/or current that is greater than a lower amount of power. In addition, the term “low-power” can be used to describe lower amounts of power. Low power can also be called control power and/or control current. Lower amounts of power, in terms of voltage, can be any voltage at or below 120 VAC.

In certain example embodiments, the protective device, the power device protected by the protective device, and/or a system that includes the example protective device is subject to meeting certain standards and/or requirements. For example, the Institute of Electrical and Electronics Engineers (IEEE) sets standards as to wiring and protection of high power electrical systems. Use of example embodiments described herein meet (and/or allow a corresponding device to meet) such standards when required.

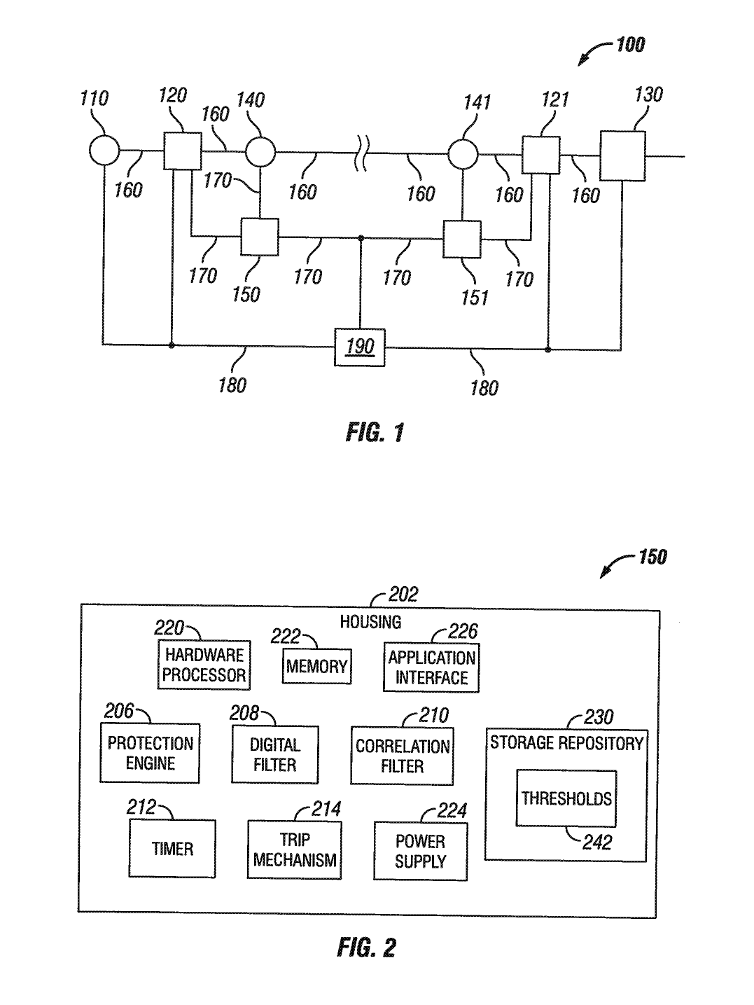

FIG. 1 shows an example protective device system 100 using an example protective device 150 in accordance with certain example embodiments. FIG. 1 includes a power source 110, a pair of breakers 120, 121, a passive load 130, a pair of sensing devices 140, 141, a pair of the example protective devices 150, 151, a number of high-power conductors 160, a number of low-power control conductors 170, a number of communication/control conductors 180, and a user 190. One or more components shown in FIG. 1 can be omitted, repeated, and/or substituted. Accordingly, embodiments of a protective device system should not be considered limited to the specific arrangements of components shown in FIG. 1. For example, one or both breakers 120 can be omitted. As another example, a motor or some other electrical device can be used in place of the power source 110.

The power source 110 is shown being electrically coupled to a breaker 120 using a high-power conductor 160. The power source 110 can provide electricity that is in AC format. The power source 110 can be physically separate from the other components of the system 100 and/or combined with another component of the system 100. The high-power conductor 160 can include one or more voltage conductors and a neutral conductor. In certain example embodiments, instead of generating power, the power source 110 can consume power, as a motor, capacitor, a transformer, or inductor. The passive load 130 can be any generating and/or consuming source of power.

In certain example embodiments, one or more conductors 160 is used to electrically couple the power source 110, the breakers 120, the passive load 130, the sensing devices 140, and/or any other components of the system 100. Each high-power conductor 160 described herein can carry voltage, current, or a combination thereof. In addition, each high-power conductor 160 described herein can be wire, cable, or other medium that can carry a voltage and/or current therethrough. The high-power conductor 160 can be made of an electrically conductive material (e.g., copper, aluminum) and can have one or more electrically non-conductive materials (e.g., rubber, nylon, plastic) wrapped around the electrically conductive material. The electrically conductive material of the conductor can be one of a number of sizes suitable to allow the high-power conductor 160 to carry the voltage and/or current required for the system 100. The amount of power (e.g., voltage, current) delivered, using the conductors 160, by the power source 110 to the breakers 120, the sensing devices 140, and the passive load 130 can be any amount suitable to operate the electrical devices electrically coupled to each other in the system 100.

The breakers 120, 121 are electrically coupled to the power source 110, the passive load 130, and each other using one or more high-power conductors 160. The breakers 120, 121 can be a manually and/or automatically operated electrical switch designed to protect an electrical circuit (e.g., the power source 110, the passive load 130) from damage caused by overload or short circuit. The breakers 120, 121 are also electrically coupled to one or more protective devices 150, 151 using conductor 170. A function of the breakers 120, 121 is to receive a trip signal from a protective device 150, 151 and, in response to the trip signal, operate (open) to interrupt continuity and immediately discontinue electrical flow. Each breaker 120, 121 can have an open position (used to discontinue electrical flow) and a closed position (used to allow electrical flow). The breaker 120, 121 can be any device that operates to change state during operations.

In certain example embodiments, when a breaker 120, 121 operates (changes state from open position to a closed position or changes state from a closed position to an open position), the switching operation of the breaker 120, 121 generates high-frequency voltage and/or current excursions, which can also be called bursts or spikes. As another example, a lighting strike can cause high-frequency voltage and/or current excursions. These spikes can penetrate through one or more sensing devices 140, 141 and carry on to the corresponding protective device 150, 151. In such a case, the spikes are superimposed with the input signal, distorting the input signal measured by the protective device 150, 151. The breakers 120, 121 shown can be the same (e.g., have the same size, voltage rating, current rating) or different from each other.

In certain example embodiments, the breakers 120, 121 are physically located in the proximity of one or more sensing devices 140. When a circuit breaker 120, 121 operates, the circuit breaker 120, 121 can generate one or more spikes, which can penetrate inside one or more protective devices 150, 151 through the corresponding sensing devices 140, 141. Operation of other nearby switching apparatus within the system 100 can also generate spike disturbances that are delivered to a protective device 150, 151 through the corresponding sensing device 140, 141.

In certain example embodiments, the sensing device 140, 141 is any device that generates (harvests) a representation of a current flowing through a conductor 160. When such a current flows through a conductor 160, the current can be called a line current. The example sensing device 140, 141 can be coupled (e.g., magnetically) to at least one conductor 160 and the corresponding protective device 150, 151. For example, the sensing device 140 can be electromagnetically coupled to a conductor 160, and electrically coupled to (capable of sending and receiving signals with respect to) the protective device 150 using conductor 170. In such a case, the sensing device 140 can clamp around and/or encircle the conductor 160.

The sensing device 140, 141 can have one or more leads 170 that carry the power harvested by the sensing device 140, 141 to the corresponding protective device 150, 151. The leads 170 (also called conductor 170) can be a form of conductor, as described above. For example, conductor 170 can be a fiber optic cable. The representation of the operating parameter (e.g., current) can be an electrical signal (e.g., analog signal, digital signal), an electro-mechanical signal, and/or any other suitable signal. The representation of the operating parameter can be a fractional amount of (proportionately smaller than) the operating parameter. The difference between the operating parameter and the representation of the operating parameter can be defined by a ratio. In one example embodiment, the representation of the operating parameter is sent by the sensing device 140, 141 to the corresponding protective device 150, 151. The representation of the operating parameter can be called an input signal. The input signal can be raw (unfiltered).

In certain example embodiments, the sensing device 140, 141 includes a primary winding and a secondary winding. The primary winding and the secondary winding typically have a known ratio (e.g., 10000:1). As a result, in such a case, the secondary winding, to which the leads 170 are electrically coupled, generates a representation of the operating parameter that is 10,000 times less than the operating parameter. The sensing device 140, 141 can also be capable of harvesting power from one or more conductors 160 in the form of one or more voltage conductors, a neutral conductor, some other conductor, or any combination thereof. Alternatively, or in addition, a different sensing device 140, 141 can be used for each conductor (e.g., each phase in an AC circuit) that make up the conductor 160.

The sensing device 140, 141 can include one or more Rogowski coils. Generally, Rogowski coils are designed with two wire loops connected in electrically opposite directions. This cancels electromagnetic fields coming from outside the coil loop. One or both loops can consist of wound wire. If only one loop is constructed as a winding, then the second wire loop can be constructed by returning the wire through or near this winding. If both loops are constructed as windings, then they must be wound in opposite directions. Two windings can be laid on top of each other or next to each other. There are different Rogowski coil designs such as split-core or non-split-core style. A Rogowski coil can be rigid or flexible. Rogowski coils are wound over a non-magnetic core, usually having toroidal shape. This core may be made of plastic, epoxy, and/or other insulating material. The coil then may be formed around a conductor 160, where the current in the conductor 160 is measured. The voltage that is induced in the Rogowski coil is proportional to the rate of change of current in the conductor 160. This rate of change of current can be called the first time derivative of the current, or di/dt, or change in current per change in time. Thus, the output of the Rogowski coil can be used to represent di/dt where “i” is the current in the conductor 160 being measured. Also, the output of a Rogowski coil can be connected to an electronic integrator circuit to provide a signal that is proportional to the sensed current.

Rogowski coils can provide low inductance and excellent response to fast-changing currents since they have air cores rather than an iron core. Without an iron core to saturate, a Rogowski coil can be highly linear even in high current applications. Furthermore, having reduced saturation concerns, a sensing device 140, 141 and associated protective device 150, 151 using a Rogowski coil can employ a single slope response with increased sensitivity. Also, the geometry of a Rogowski coil may provide a sensing device 140, 141 that is significantly immune to electromagnetic interference. In certain example embodiments, the effect of a spike can be more pronounced when using a Rogowski coil in the sensing device 140, 141 because the Rogowski coil is frequency-dependent, which means that the Rogowski coil can amplify higher frequencies with a linear relationship between the coil output signal and frequency.

The power harvested by the sensing device 140, 141 from the conductor 160 and the resulting input signal delivered to the corresponding protective device 150, 151 can generate the power required to operate one or more components (e.g., the hardware processor) of the protective device 150, 151. In addition, or in the alternative, one or more components of the protective device 150, 151 can be powered from a separate auxiliary power source (not shown), which can include but is not limited to 120VAC service and/or a battery. Part of the protective device 150, 151 in FIG. 1 is electrically and/or communicably coupled to the user 190 using conductor 180. Specifically, conductor 180 electrically couples the protective devices 150, 151 to the user 190 and each other. Conductor 180 can be a conductor delivering control power (as described above with respect to conductor 170, such as a fiber optic cable or an Ethernet system) a wireless communication system, or any combination thereof. In certain example embodiments, conductor 180 is the same as conductor 170.

Details of the components of the protective devices 150, 151 are described below with respect to FIG. 2. In general, each protective device 150, 151 communicates with the user 190 to receive instructions (e.g., new settings) and/or to notify the user 190 that a trip signal has been sent to a breaker 120, 121. The protective device 150, 151 generates and sends a trip signal when a fault condition is detected by the protective device 150, 151. When the breaker 120, 121 operates (opens) in response to a trip signal generated by a protective device 150, 151, one or more circuits are opened to prevent the condition causing the fault from causing damage to one or more components in the system 100. In certain example embodiments, the protective device 150, 151 monitors for a fault condition and, when a fault condition exists, both sends the trip signal to the breaker 120, 121 and sends a notification to the user 190 that the trip signal was sent. In such a case, the protective device 150, 151 can generate and send a trip signal that is sent directly to the breaker 120, 121. The protective device 150, 151 can also send a trip signal to the user 190 for information purposes. In such a case, when the trip signal is generated and sent, the protective device 150, 151 is said to operate.

Generally, when a protective device 150, 151 generates and sends a trip signal, one or more devices (e.g., breaker 120, 121) in the system 100 are electrically isolated. In addition, each protective device 150, 151 can be electrically and/or communicably coupled to each other using the conductor 170. In such a case, the protective devices 150, 151 can send signals measured by their respective sensing devices 140, 141 to each other to determine if a fault condition exists. For example, protective device 150 can receive the signal measured by sensing device 141 and sent by protective device 151 to compare such signal with the signal measured by sensing device 140 to determine if the differential current (in this case, the input signal for protective device 150) exceeds a differential current threshold level.

Each protective device 150, 151 can monitor one or more of a number of different electrical conditions, also called a fault or fault condition. One such electrical condition is an overcurrent condition. In one example embodiment, an overcurrent condition is where one or more conductors 160 transmitting power carries a current that is too high (i.e., has too many amperes) relative to a threshold current. For example, if a threshold current is 120 Amperes (A) and the current flowing through a conductor 160 is 220 A, then an overcurrent condition exists. An overcurrent condition can also be caused by one or more of a number of other conditions, including but not limited to excessive power demand by a load, internal dielectric degradation, and/or an internal short circuit in an electrical connector.

In certain example embodiments, a user 190 is communicably coupled to one or more of the protective devices 150, 151. A user 190 can be any person that interacts with the system 100 that includes a protective device 150, 151. Examples of a user 190 can include, but are not limited to, an electric distribution company, an electric transmission company, a public utility, a control room operator, a load management system, an engineer, an electrician, an instrumentation and controls technician, a mechanic, an operator, a consultant, a contractor, and a manufacturer's representative.

A user 190 can communicate with a protective device 150, 151 using a physical interaction (e.g., touching a touch pad on the protective device 150) and/or using a user system (not shown). In cases where a user 190 uses a user system to communicate with a protective device 150, 151, the user system can use wired and/or wireless technology. The user system is described more fully below with respect to FIG. 2 and the application interface of the protective device.

FIG. 2 shows an example protective device 150 in accordance with certain example embodiments. The example protective device 150 of FIG. 2 includes a housing 202, inside of which can include a power source 204, a protection engine 206, a digital filter 208, a correlation filter 210, a timer 212, a trip mechanism 214, a hardware processor 220, memory 222, an application interface 226, and a storage repository 230 that includes thresholds 242. In one or more embodiments, one or more of the components shown in FIG. 2 can be omitted, repeated, and/or substituted. Accordingly, embodiments of protective devices should not be considered limited to the specific arrangements of components shown in FIG. 2.

In certain example embodiments, the housing 202 is a type of enclosure houses one or more of the components of the protective device 150. The housing 202 can have a movable portion that allows a user to access the one or more components of the protective device 150 located inside the housing 202. The housing 202 can be made of one or more of a number of suitable materials, including but not limited to plastic, metal, glass, and rubber. The housing 202 can be mounted in one or more locations when connected to the system 100. For example, the housing 202 can be mounted in or near a compartment that houses the corresponding breaker 120. As another example, the housing 202 can be mounted in or near a central relay station.

In certain example embodiments, the power supply 224 is operatively coupled to the hardware processor 220 and any other components of the protective device 150. The power supply 224 can be one or more sources of energy (e.g., electricity) used to provide power and/or control to the hardware processor 220 and/or any other component of the protective device 150. The power supply 224 typically provides electricity that is in AC format and/or DC format. The power supply 224 can be physically separate from the other components of the protective device 150 and/or internal within the housing 202 of the protective device 150.

The amount of power delivered by the power supply 224 to the hardware processor 220 can be any amount suitable to operate the hardware processor 224. In certain example embodiments, the power delivered by the power supply 224 is transformed, rectified, inverted, and/or otherwise manipulated, at the power supply 224, so that the hardware processor 220 and/or other various components of the protective device 150 receive a proper voltage and/or current level to operate properly. In certain example embodiments, the signal received from a sensing device 140, 141 acts as the power supply 224 by providing power to the hardware processor 220 and/or other components of the protective device 150.

In certain example embodiments, the power supply 224 can be a battery. The battery can provide power to the hardware processor 220 and/or other components of the protective device 150 on a constant basis or as backup power when a different power supply 224 fails. The battery and/or power supply 224 can be disposed inside of the housing 202, affixed to the housing 202, or placed in a location remote from the housing 202. The power supply 224 and/or the battery can be electrically coupled to the hardware processor 220 and/or other components of the protective device 150 using a wired and/or wireless technology.

The hardware processor 220 receives power from the power source 224 and is communicably coupled, at least, to the timer 212, the application interface 226, the memory 222, and the protection engine 206. In general, the protection engine 206, using one or more instructions executed on the hardware processor 220 and using software stored in the memory 222, determines whether a power spike exists, whether a fault exists, where the fault exists, and, as appropriate, sends a trip signal to a breaker 120, 121. If a trip signal is sent to a breaker 120, 121, the protection engine 206 can also use the application interface 226 and the conductors 170 to inform the user 190 that the trip signal was sent.

The example hardware processor 220 within the housing 202 of the protective device 150 is configured to execute software in accordance with one or more example embodiments. Specifically, the hardware processor 220 is configured to execute the instructions used to operate the protection engine 206 and/or any other components within the protective device 150. The example hardware processor 220 is an integrated circuit, a central processing unit, a multi-core processing chip, a multi-chip module including multiple multi-core processing chips, or other hardware processor. The hardware processor 220 can be known by other names, including but not limited to a computer processor, a microcontroller, a microprocessor, and a multi-core processor.

In one or more example embodiments, the hardware processor 220 is configured to execute software instructions stored in the memory 222 of the protective device 150. The example memory 222 can include one or more cache memories, main memory, and/or any other suitable type of memory. In certain example embodiments, the memory 222 is discretely located within the housing 202 relative to the hardware processor 220. In certain configurations, the memory 222 can also be integrated with the hardware processor 220. The hardware processor 220 can be integrated into one or more mixed signal integrated circuits. In such a case, the profile and/or cost of the hardware processor 220 can be reduced.

In certain example embodiments, the protection engine 206 of the protective device 150 coordinates the digital filter 208, the correlation filter 210, the timer 212, and the trip mechanism 214. Specifically, the protection engine 206 sends data (e.g., signals, instructions) to the digital filter 208, the correlation filter 210, the timer 212, and the trip mechanism 214. Similarly, the protection engine 206 receives data (e.g., input signal, time) from the digital filter 208, the correlation filter 210, the timer 212, and the trip mechanism 214. More specifically, the protection engine 206 receives, using the application interface 226, one or more input signals (e.g., current) from the sensing devices 140, 141. The protection engine 206 can continually read the input signals or sample the input signals. When the protection engine 206 samples the input signals, the sampling rate can be based on one or more of a number of factors, including but not limited to a default sampling rate, a sampling rate defined by the user 190, a sampling rate stored in the storage repository 230, some other factor, or any combination thereof. An example of a sampling rate is 16 samples per cycle. The sampling rate can be random or substantially constant. In certain example embodiments, the sampling rate is the same for all types (raw signals, filtered signals, etc.) of input signals used herein.

Upon receiving the input signals (either unfiltered or filtered by an analog filter) (herein called simply a “signal”) from one or more sensing devices 140, 141, the protection engine 206 retains a copy of the input signal for processing according to example embodiments and also sends a copy of the input signal to a filter. This latter copy, after going through an existing digital filter 208, becomes a filtered signal and is processed by the protection engine 206 according to method presently known in the art for such a protective device. As for the copy of the unfiltered input signal that is retained by the protection engine 206 for processing according to example embodiments, the protection engine 206 sends the unfiltered input signal to the correlation filter 210 with instructions on how the correlation filter 210 is to compare the signals. The correlation filter 210 can use one or more of a number of comparison algorithms, which may be stored in the storage repository 230. In such a case, the protection engine 206 can retrieve the appropriate comparison algorithm(s) from the storage repository 230 and send the appropriate comparison algorithm(s) to the correlation filter 210 along with the signals to be compared.

An example of a comparison algorithm is applying a time adjustment (e.g., 0.005 seconds) to one signal and subsequently performing simple subtraction of the signals. Another example of a comparison algorithm is multiplying one of the signals by a multiple (e.g., two, one halt), then subtracting the signals, and then taking the absolute value of the difference. Yet another example of a comparison algorithm is comparing each signal to one or more threshold values, where the threshold values can be among the thresholds 242 stored in the storage repository 230. Still another comparison algorithm determines how often a sample is taken from the stream of unfiltered input signals.

The correlation filter 210 can receive multiple signals from the protection engine 206, where each signal is generated by a different sensing device 140, 141. In such a case, the correlation filter 210 uses the appropriate comparison algorithm to compare one or both input signals. In certain example embodiments, the correlation filter 210 uses a type (e.g., discrete) of Fourier transform to filter the signals and determine whether an input signal that exceeds a threshold value is a power spike. As another example, the correlation filter 210 conducts a point-on-wave comparison of samples of two digitized waveform data streams. The two digitized waveform data streams can be, for example, the unfiltered input signals and corresponding samples of the filtered signals, as with the filter algorithm using a Fourier transform. In such a case, both data streams are sampled at the same rate (e.g., at least 16 samples per cycle), and the resulting data is used to determine if a power spike exists. For example, a power spike would exist if, using the algorithm described above, a significant difference existed between the magnitude of the two signals such that the difference exceeded a threshold value. The protection engine 206 can determine, based on the algorithms used by the correlation filter 210, which threshold values are needed, retrieves those threshold values from the thresholds 242 in the storage repository 230, and sends the threshold values to the correlation filter 210.

Once the correlation filter 210 has run its algorithm(s), the correlation filter 210 notifies the protection engine 206 whether a power spike is detected. In certain example embodiments, when the protection engine 206 is notified by the correlation filter 210 that a power spike is detected, the protection engine 206 sends an instruction (signal) to the timer 212 to start measuring a time period. In certain example embodiments, the timer 212 tracks clock time and/or tracks one or more time periods, such as the time period and an inherent delay time. The example timer 212 is able to track one or more time periods concurrently. The timer 212 can be part of the hardware processor 220. The timer 212 can track time periods based on an instruction received from the protection engine 206, based on an instruction received from the user 190, based on an instruction programmed in the software for the protective device 150, 151, based on some other condition, or from any combination thereof.

The time period can be any length of time. For example, the time period can be approximately 0.01 seconds. A time period can be measured in seconds and/or in one or more other measurements. For example, for a circuit with AC power, the time period can be two cycles. The duration of each time period (e.g., the time period) can be stored in the timer 212 and/or in the storage repository 230. The duration of each time period can be set by default, by a user 190, by software instructions, by the protection engine 206, and/or by any other suitable means. In certain example embodiments, the time period is no more than 3 cycles. When a time period has ended (expired, lapsed), the timer 212 sends a signal to the protection engine 206 to notify the protection engine 206 that such a time period has ended.

In addition, if the protection engine 206 is notified that a power spike is detected, the protection engine 206 can disable the trip mechanism 214 of the protective device 150. In certain example embodiments, the trip mechanism 214 generates a trip signal that is sent to one or more breakers 120, 121. Such a trip signal, when received by a breaker 120, 121, forces the breaker to open immediately. When a breaker 120, 121 is opened, the portion of the system 100 fed by the breaker 120, 121 becomes electrically isolated. If the trip mechanism 214 is disabled, the trip mechanism 214 cannot generate a trip signal, even if the logic of the protection engine 206 that is processing the filtered input signal (filtered by the digital filter 208) determines that a fault exists. By contrast, if the trip mechanism 214 is enabled, the trip mechanism 214 is able to generate a trip signal when the logic of the protection engine 206 that is processing the filtered input signal (filtered by the digital filter 208) determines that a fault exists.

Optionally, in certain example embodiments, the trip mechanism 214 can also generate an information notification for a user 190, indicating that a trip signal was sent to a breaker 120, 121. In such a case, when the protection engine 206 disables the tip mechanism 214 based on the detection of a power spike by the correlation filter 210, the trip mechanism 214 cannot send such an information notification to the user 190.

Further, if the protection engine 206 is notified by the correlation filter 210 that a power spike is detected, the protection engine 206 can disable a complementary trip mechanism 214 of a complementary protective device 151. The complementary trip mechanism 214 of the complementary protective device 151 can be substantially similar to the trip mechanism 214 of the protective device 150 described above. The complementary protective device 151 can be the same or different than the protective device 150. In either case, the protective devices 150, 151 are configured to communicate with each other using the conductors 170. There can be one complementary protective device 151 or multiple complementary protective devices.

In certain example embodiments, the protection engine 206 disables the trip mechanism of the protective device 150, disables the complementary trip mechanism 214 of the complementary protective device 151, and instructs the timer 212 to start measuring the time period at substantially the same time. Specifically, the protection engine 206 disables the trip mechanism of the protective device 150, disables the complementary trip mechanism 214 of the complementary protective device 151, and instructs the timer 212 to start measuring the time period substantially simultaneously when protection engine 206 determines that the filtered input signal exceeds a threshold value.

In certain example embodiments, the protection engine 206 determines, after being notified by the correlation filter 210 that a power spike is detected and during the time period measured by the timer 212, whether a fault exists. Specifically, when the correlation filter 210 detects a power spike in the input signal, the protection engine 206 determines whether the input signal exceeds a threshold value. The protection engine 206 can follow one or more protocols to make such a determination. For example, the protection engine 206 can compare the unfiltered signal to one or more threshold values, which are retrieved from the thresholds 242 stored in the storage repository 230. As another example, a fault can only be deemed to exist by the protection engine 206 if a certain minimum number (e.g., three, four, five) of consecutive samples of the input signal exceed a threshold amount.

In certain example embodiments, the protection engine 206 determines, if the protection engine 206 determines that a fault exists, whether the fault originated between the sensing device 140 and the sensing device 141 (which can be described more generically herein as being between the protective device 150 and the complementary protective device 151). The protective device 150 can use the complementary protective device 151 to determine whether the fault originated between the protective device 150 and the complementary protective device 151.

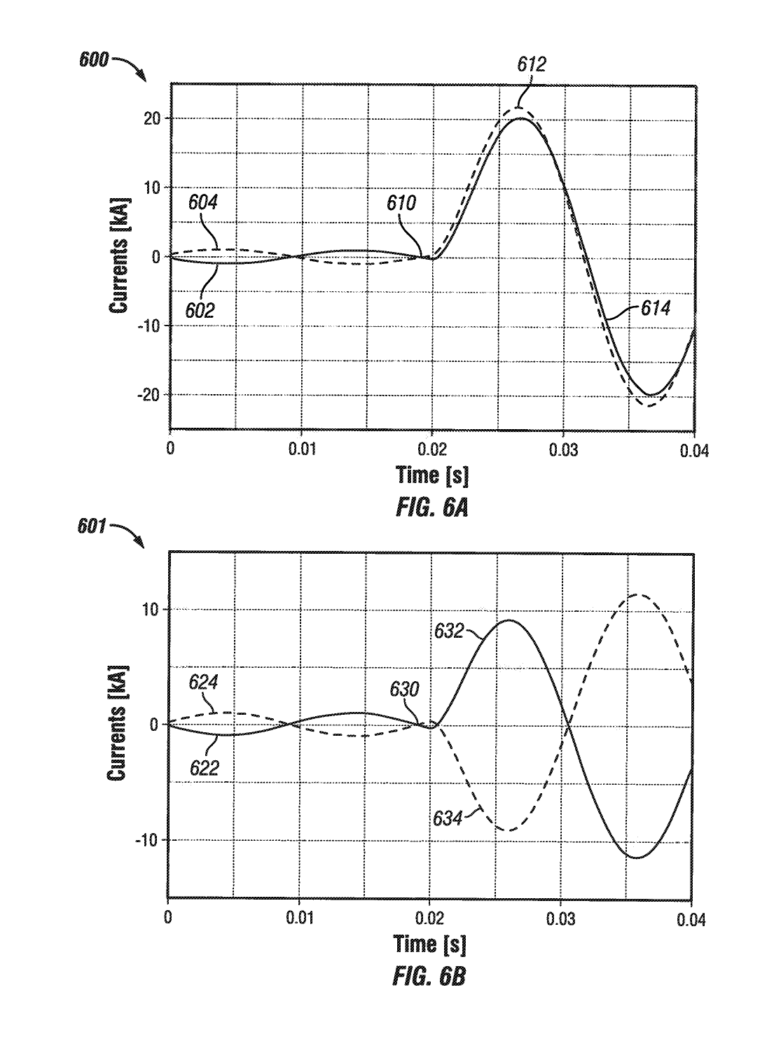

For example, the protection engine 206 can compare the signal generated by the sensing device 140 with the signal generated by the sensing device 141 (adjusted for time delay, if necessary) and determine wither such signals are substantially in phase or substantially out of phase. The fault originates in a region between the sensing device 140 and the complementary sensing device 141 when the polarity of the signal generated by the sensing device 140 has a polarity substantially similar to the polarity of the signal generated by the sensing device 141. Alternatively, the fault originates outside the region between the sensing device 140 and the complementary sensing device 141 when the signal generated by the sensing device 140 has a polarity substantially opposite to the polarity of the signal generated by the sensing device 141. Graphical examples of in-phase and out-of-phase polarities of the signals are described below with respect to FIGS. 6A and 6B.

In certain example embodiments, during the remainder of the time period measured by the timer 212, the protection engine 206 compares the input signal with the threshold values to determine whether the input signal exceeds a threshold value. If the protection engine 206 determines that the input signal does not exceed a threshold value during the remainder of the time period, then the input signal is within a normal range, and the initial excursion (power spike) detected in the input signal by the correlation filter 210 (causing the timer 212 to start measuring the time period) was merely an isolated power spike. In such a case, once the time period has expired, the protection engine 206 enables the trip mechanism 214 of the protective device 150 (and, in some cases, the trip mechanism 214 of the complementary protective device 151). Because the protection engine 206 determines that a fault does not exist and that the power spike was isolated, the trip mechanism 214 of the protective device 150 (and, in some cases, the trip mechanism 214 of the complementary protective device 151) are enabled but do not generate a trip signal.

On the other hand, if the protection engine 206 determines that the input signal exceeds a threshold value during the remainder of the time period, then the input signal is part of a fault condition. In such a case, if the protection engine 206 determines that the fault originates in a region between the sensing device 140 and the complementary sensing device 141, then the trip mechanism 214 of the protective device 150 (and, in some cases, the trip mechanism 214 of the complementary protective device 151) is enabled by the protection engine 206. With the trip mechanism 214 of the protective device 150 and the complementary protective device 151 enabled, the trip mechanism 214 can generate a trip signal upon the protection engine 206 detecting the fault.

On the other hand, if the protection engine 206 determines that the fault originates outside the region between the sensing device 140 and the complementary sensing device 141, then the trip mechanism 214 of the protective device 150 (and, in some cases, the tip mechanism 214 of the complementary protective device 151) remain disabled for the remainder of the time period.

If the time period, as measured by the timer 212, ends without the protection engine 206 detecting a fault that originates in a region between the sensing device 140 and the complementary sensing device 141, then the protection engine 206 enables the trip mechanism 214 of the protective device 150 and the trip mechanism 214 of the complementary protective device 151.

Continuing with FIG. 2, the protective device 150 interacts with the user 190 using an application interface 226 in accordance with one or more example embodiments. Specifically, the application interface 226 of the protective device 150 receives input from and sends output to the user 190. The user 190 can include an interface to receive data from and send data to the protective device 150 in certain example embodiments. Examples of this interface include, but are not limited to, a graphical user interface, an application programming interface, a keyboard, a monitor, a mouse, a web service, a data protocol adapter, some other hardware and/or software, or any suitable combination thereof.

In one or more embodiments of the invention, the information received by the application interface 226 includes, but is not limited to, relay settings and thresholds 242. The information sent by the application interface 226 can include, but is not limited to, a notification that a trip signal has been sent to a breaker 120, 121. The information sent by the application interface 226 specifies, but is not limited to, a user 190, a field location, a data source, a Uniform Resource Identifier (URI) (e.g., a Uniform Resource Locator (URL), a web address, etc.), data identified by and/or requested by the protection engine 206, some other software or source of information, or any suitable combination thereof.

In one or more embodiments of the invention, the information (i.e., data) transferred among the application interface 226, the user 190 corresponds to metadata associated with such information. In this case, the metadata describes the data specified (i.e., the metadata provides context for the specified data). In one or more embodiments of the invention, the protective device 150 supports various data formats provided by the user 190.

Continuing with FIG. 2, the protective device 150 retrieves and stores thresholds 242. More specifically, the protective device 150 uses the protection engine 206 to retrieve and store thresholds 242 in the storage repository 230 in accordance with one or more example embodiments. In one or more example embodiments, the thresholds 242 of the storage repository 230 are a measure of one or more of a number of data points and/or parameters. Specifically, the thresholds 242 represent values or ranges of values that measure the strength of a data point (e.g., the magnitude of an input signal). The storage repository 230 can also store one or more of a number of other types of data, including but not limited to filter algorithms, comparison algorithms, and time periods.

The storage repository 230 can be a persistent storage device (or set of devices) that stores software and data used to assist the protection engine 206 in determining a threshold to compare against an input signal received from a sensing device 140. In one or more example embodiments, the storage repository 230 stores the thresholds 242. Examples of a storage repository 230 include, but are not limited to, a database (or a number of databases), a file system, a hard drive, some other form of data storage, or any suitable combination thereof. The storage repository 230 is located on multiple physical machines, each storing all or a portion of the thresholds 242 according to some example embodiments. Each storage unit or device is physically located in the same or different geographic location.

The storage repository 230 is operatively connected to the protection engine 206 and the correlation filter 210. In one or more example embodiments, the correlation filter 210 detects a power spike. After the power spike is detected, the protection engine 206 includes functionality to receive an input signal (or, more simply, a signal) from a sensing device 140, 141, determine that the input signal exceeds a corresponding threshold value (indicating a fault), and (after determining that the fault originates in a region between the sensing devices 140, 141) enable the trip mechanism 214. More specifically, the protection engine 206 sends information to and/or receives information from the storage repository 230 in order to determine whether to disable the trip mechanism 214 based on the occurrence of a power spike.

The functions of the protection engine 206 can be performed on a single computing device or on multiple computing devices. Further, the functions of the protection engine 206 can be performed on the same computing device that performs the functions (e.g., digital filtering, fault detection using a filtered signal) of a protective device currently known in the art. When the functions of the protection engine 206 are performed on multiple computing devices, a number of configurations and/or frameworks are used in certain example embodiments. The configurations and/or software frameworks are designed to work with multiple data nodes and large quantities of data. One or more calculations performed by one or more components of the protection engine 206 are performed on multiple machines operating in parallel, where the results from each machine are combined to generate a result to the one or more calculations.

Each component of the protective device 150 described herein (e.g., the protection engine 206, the correlation filter 210, and the trip mechanism 214) uses one or more algorithms to perform one or more calculations. Each algorithm is designed to receive specific types of data and generate one or more specific results using such data. A specific result is a number, a range of numbers, a rating, and/or some other suitable output according to some example embodiments. Each algorithm is fixed, variable, self-adjusting, or otherwise changed. Each algorithm uses one or more pieces of data from one or more areas of data (e.g., thresholds 242).

In one or more embodiments of the invention, the protection engine 206 of the protective device 150 coordinates the correlation filter 210, the timer 212, the trip mechanism 214, and the storage repository 230. Specifically, the protection engine 206 coordinates the transfer of information between the application interface 226, the storage repository 230, and the other components of the protective device 150 according to certain example embodiments.

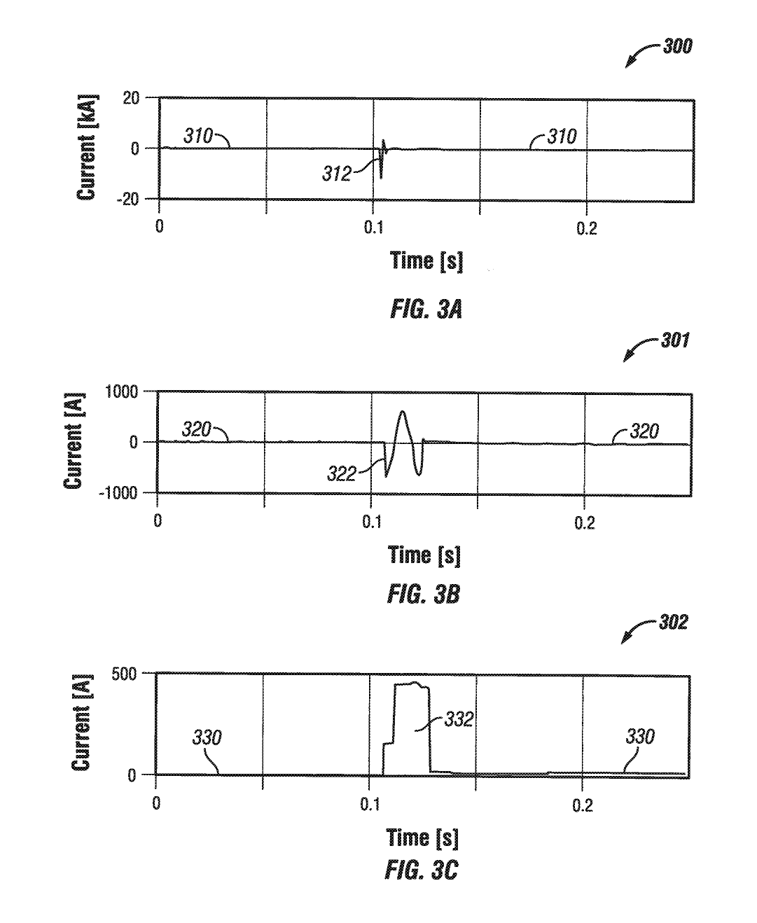

FIGS. 3A-C show various graphs of signals for an example protective device in accordance with certain example embodiments. Referring to FIGS. 1-3C, the input signal of FIGS. 3A-C includes different versions of a power spike that is not part of a fault. For example, the power spike can be generated by closing a breaker 120. FIG. 3A shows a graph 300 of the signal 310 with the power spike 312 in raw form. The signal 310 and corresponding power spike 312 of FIG. 3A is measured by the sensing device 140 located in proximity to the breaker 120. The power spike 312 corresponds to an operation of (closing) the breaker 120. The power spike 312 lasts for approximately one half of one cycle and starts just after 0.1 seconds. The power spike 312 peaks at approximately −13 kA. Prior to and shortly after the power spike 312, the current of the signal 310 is at a normal level (approximately close to one kA, although normal operating current can vary depending on the system components).

In the graph 301 in FIG. 3B, a filtered version of the signal 320 is shown after going through the digital filter 208 of the protective device 150. In this case, the filter extends the length (approximately 0.016 seconds, or one cycle) and decreases the magnitude (approximately 750 A) of the power spike 322. Again, the signal 320 is at a normal level prior to and shortly after the power spike 322.

FIG. 3C shows a graph 302 of a differential current 330 (derived by the protective device 150) comparing the filtered signal 320 of FIG. 3B and a filtered signal measured by the sensing device 141 and digitally filtered by the digital filter 208. The filtered signal measured by the sensing device 141 can be filtered by the digital filter 208 of protective device 150 or by the digital filter 208 of protective device 151. In either case, the signal measured by the sensing device 141 is sent from protective device 151 to protective device 150 using conductor 180.

The differential current 330 of FIG. 3C can be generated by the protection engine 206 of the protective device 150. The power spike 332 of the differential current 330 has approximately the same duration and magnitude as the power spike 322 shown in FIG. 3B. This means that the effects of the breaker 120 switching, as measured by the sensing device 140, did not travel along the conductor 160 to reach sensing device 141 to be measured. In other words, the power spike created by the operation of the breaker 120 has a stronger magnitude at the sensing device 140 and a lower magnitude at the sensing device 141.

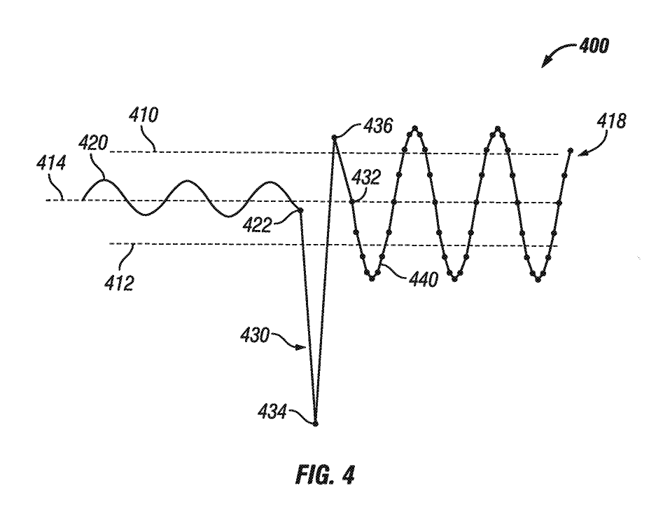

FIG. 4 shows a graph 400 of a raw signal 418 that includes a spike 430 and fault condition 440 in accordance with certain example embodiments. The graph 400 shows a zero axis 414 (depicting a zero value of the raw signal 418), as well as a positive threshold value 410 and a negative threshold value 412 spaced equidistantly above and below the zero axis 414, respectively. The raw signal 418 has a normal shape in a steady-state condition 420 until a time corresponding to point 422, where a power spike 430 occurs. The power spike 430 has negative peak 434 that exceeds the negative threshold value 412 and a positive peak 436 that exceeds the positive threshold value 410.

The power spike 430 lasts approximately one half of one cycle until a time corresponding to point 432. After the time corresponding to point 432, the raw signal 418 has an amplified shape associated with a fault condition 440. The amplified shape of the fault condition 440 is symmetrical and cyclic, similar to the normal shape of the steady-state condition 420. However, the magnitude of the fault condition 440 is greater than the amplitude of the steady-state condition 420 such that the apexes of the fault condition 440 exceed the positive threshold value 410 at the positive portions of the fault condition 440 and exceed the negative threshold value 412 at the negative portions of the fault condition 440.

In certain example embodiments, a power spike 430 can exist as a precursor to a fault condition 440 or in the absence of a fault condition 440 (as during a normal breaker operation). If the power spike 430 exists as a precursor to a fault condition 440, the input signal for the subsequent time after the power spike 430 (e.g., after point 432 in FIG. 4) can simply be called a fault 440.

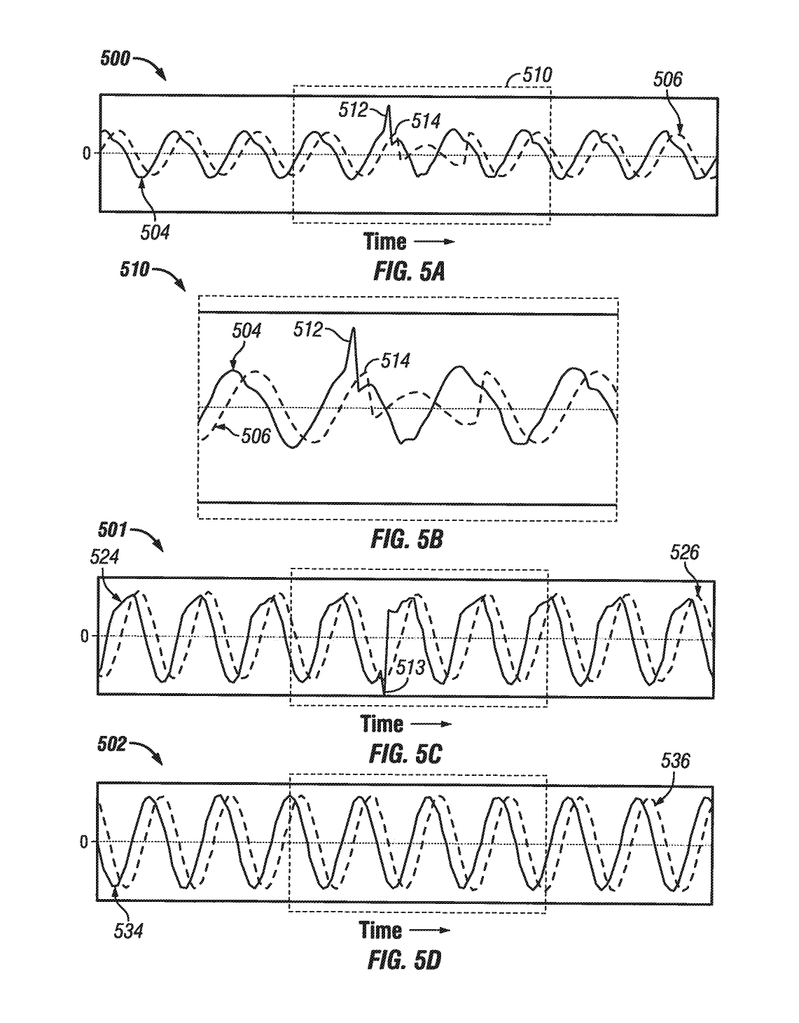

FIGS. 5A-D show various graphs of a raw and filtered input signal for each phase of an AC signal in accordance with certain example embodiments. Referring to FIGS. 1-5D, FIG. 5A shows a graph 500 of the A-phase of the raw (unfiltered) input signal 504 and the filtered signal 506. The slight delay in time of the filtered signal 506 relative to the raw signal 504 is due to processing by the digital filter 208 and communication between the digital filter 208 and the protection engine 206. FIG. 5B shows a graph 510 detailing a power spike 512 in the raw signal 504 and the filtered signal 506 of the A-phase. Generally, the filtered signal 506 is an averaging of the unfiltered signal 504 over some number of consecutive samples. In this case, due to the averaging of the filtering process, the power spike 514 affects the filtered signal 506 for approximately one cycle, and the magnitude of the power spike 514 is dampened relative to the power spike 512 of the raw input signal 504.

FIG. 5C shows a graph 501 of the B-phase of the raw signal 524 and the filtered signal 526. In FIG. 5C, the raw signal 524 shows some signs of the power spike 513, but the filtered signal 526 is substantially unaltered by the power spike. FIG. 5D shows a graph 502 of the C-phase of the raw signal 534 and the filtered signal 536. As in FIG. 5C, the filtered signal 536 in FIG. 5D is substantially unaffected by the power spike.

FIGS. 6A and 6B show graphs of an in-zone fault 610 and an out-of-zone fault 630, respectively, in accordance with certain example embodiments. Referring to FIGS. 1-6B, FIG. 6A shows a graph 600 of an in-zone fault 610, which is where the fault 610 originates in a region between the protective device 150 and the complementary protective device 151. Prior to the fault 610 in FIG. 6A, the input signal 602 (in this case, the raw input signal) from the sensing device 140 (associated with the protective device 150) is a substantially mirror image of the input signal 604 (in this case, the raw input signal) from the sensing device 141 (associated with the protective device 151) relative to zero current. After the in-zone fault 610 occurs, the input signal 612 from the sensing device 140 is substantially in phase with the input signal 614 from the sensing device 141. In such a case, the protection engine 206 determines that the fault 610 originates in a region between the protective device 150 and the complementary protective device 151.

FIG. 6B shows a graph 601 of an out-of-zone fault 630, which is where the fault 630 originates outside the region between the protective device 150 and the complementary protective device 151. Prior to the fault 630 in FIG. 6B, the input signal 622 (in this case, the raw input signal) from the sensing device 140 (associated with the protective device 150) is a substantially mirror image of the input signal 624 (in this case, the raw input signal) from the sensing device 141 (associated with the protective device 151) relative to zero current. After the in-zone fault 630 occurs, the input signal 632 from the sensing device 140 remains substantially out of phase with the input signal 634 from the sensing device 141. In such a case, the protection engine 206 determines that the fault 630 originates outside the region between the protective device 150 and the complementary protective device 151.

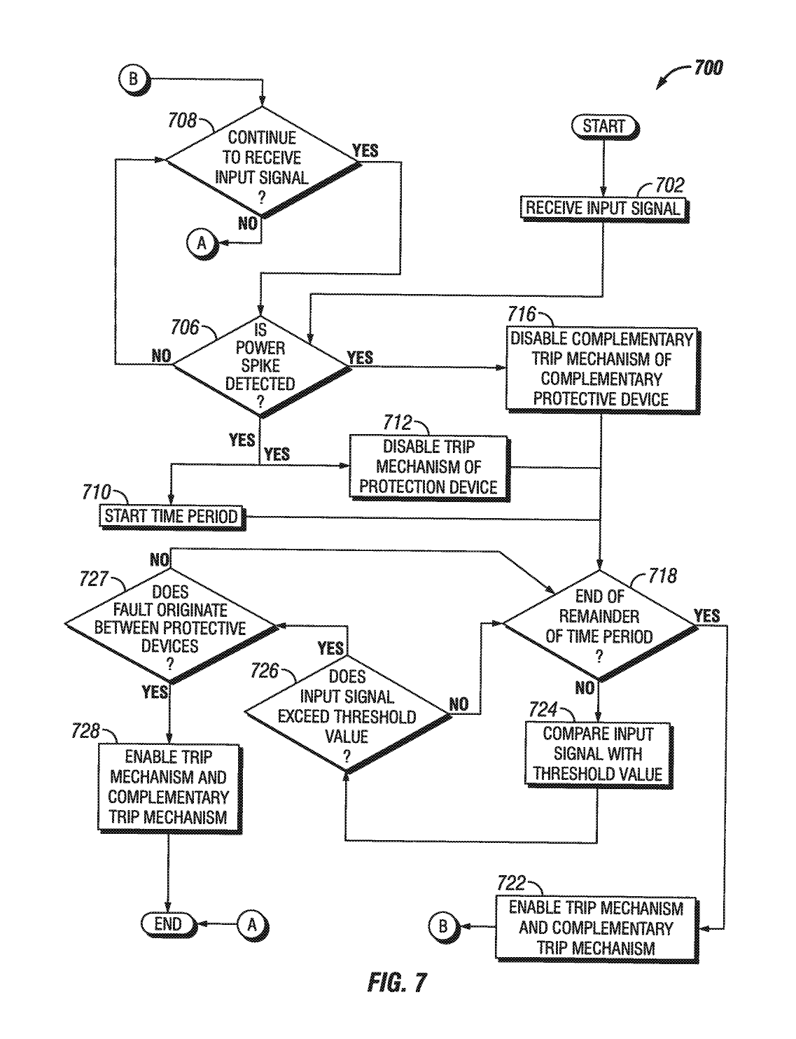

FIG. 7 shows a flowchart of a method 700 for detecting a likely fault for a protective device in accordance with certain example embodiments. While the various steps in these flowcharts are presented and described sequentially, one of ordinary skill will appreciate that some or all of the steps may be executed in different orders, may be combined or omitted, and some or all of the steps may be executed in parallel. Further, in certain example embodiments, one or more of the steps described below may be omitted, repeated, and/or performed in a different order.

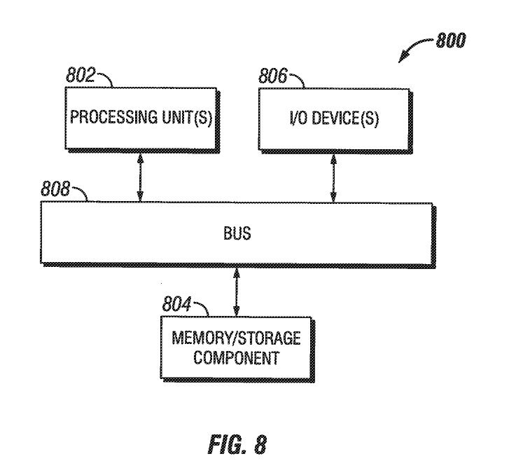

In addition, a person of ordinary skill in the art will appreciate that additional steps, omitted in FIG. 7, may be included in performing these methods. Accordingly, the specific arrangement of steps shown in FIG. 7 should not be construed as limiting the scope. In addition, a particular computing device, as described, for example, in FIG. 8 below, may be used to perform one or more of the steps for the method 700 described below.

Referring now to FIGS. 1-7, one example method 700 begins at the START step and continues to step 702. In step 702, an input signal is received. The input signal can be the original input signal or a copy of the input signal. In certain example embodiment, the input signal is a raw (unfiltered) signal. An unfiltered signal can be a signal that has gone through no filtering or through some preliminary analog filtering (e.g., 1 kHz lowpass, 0.5 Hz hipass, 6.94 kHz lowpass). In either case, the input signal has not gone through more extensive filtering (e.g., 64 sample cosine filtering, digital filtering) that is required for use by the remainder of the protective device (or a traditional solid-state protective device).

The input signal can be a single signal or multiple signals. The input signal is received by the protection engine 206 of the protective device 150. In certain example embodiments, one or more components of the protective device 150, 151 are used to process the signal sent by the sensing device 140, 141 to generate the input signal. As an example, the correlation filter 210 can receive multiple signals (e.g., raw, unfiltered signals, analog-filtered signals) and generate the input signal by taking the difference between the multiple signals. Alternatively, the protection engine 206 can receive one or more input signals from one or more sensing devices 140, 141, with or without processing of the input signals. The input signal can be originated by a measuring device 140, 141 and received by a protective device 150, 151.

In step 706, a determination is made as to whether a power spike is detected. In certain example embodiments, the correlation filter 210 identifies that a high-frequency spike has been received from the sensing device 140, 141. The correlation filter 210 can detect the onset of a power spike and differentiate the power spike from a fault by using one or more of a number of correlation factors. Thus, the correlation filter 210 can prevent false operation caused by a spike.

In certain example embodiments, the correlation filter 210 detects a power spike based on whether the input signal exceeds a threshold value. The threshold value can be among the thresholds 242 stored in the storage repository 230. The threshold value can be retrieved by the protection engine 206. In certain example embodiments, the correlation filter 210 compares the input signal and the threshold value and determines whether the input signal exceeds the threshold value for a power spike. The threshold value can be a range of values. The threshold value can be a positive value, a negative value, or an absolute value. As an example, the threshold value is exceeded (and a power spike may be declared) if the input signal is greater than the absolute value of the threshold value.

If the input signal exceeds a threshold value, then the correlation filter 210 determines whether this portion of the input signal is a power spike. The threshold value can be some multiple (e.g., ten, fifteen) times greater than an average of the input signal prior to the time period. If a power spike in the input signal is detected, then the process proceeds to steps 710, 712, and 716 at substantially the same time. If a power spike in the input signal is not detected (e.g., if there is a fault current without a power spike), then the process proceeds to step 708.

In step 708, a determination is made as to whether the input signal continues to be received. The input signal can be the same or a different input signal compared to that received in step 702 above. In certain example embodiments, the input signal is a continuous signal. The input signal can be generated by one or more sensing devices 140, 141 and received by one or more protective devices 150, 151. The one or more protective devices 150, 151 can determine whether the input signal continues to be received. If the input signal continues to be received, then the process reverts to step 706. In such a case, the process forms a continuous loop between steps 706 and 708 until the input signal is no longer received or until a power spike from the input signal is detected. If the input signal is no longer received, then the method 700 ends at the END step.

In step 710, the time period is started. The time period is started and measured by the timer 212. In certain example embodiments, the protection engine 206 sends a command to the timer 212 to start measuring the time period. The time period can be set and/or adjusted by default, by a user 190, by some other component, and/or by the protection engine 206 according to software instructions. The time period can be any period of time that allows the protection engine 206 to analyze the input signal to determine whether a fault condition truly exists and, if so, where the fault condition originates. For example, the time period can be approximately 1 to 1½ cycles.

In step 712, the trip mechanism 214 of the protective device 150 is disabled. In certain example embodiments, disabling the trip mechanism 214 of the protective device 150 prevents the trip mechanism 214 from sending a signal to open a breaker 120, 121. The protection engine 206 of the protective device 150 can disable the trip mechanism 214 of the protective device 150. In step 716, the complementary trip mechanism 214 of the complementary protective device 151 (at times also called the trip mechanism 214 of the complementary protective device 151) is disabled. In certain example embodiments, disabling the trip mechanism 214 of the complementary protective device 151 prevents the trip mechanism 214 from sending a signal to open a breaker 120, 121. The protection engine 206 of the protective device 150 can disable the complementary trip mechanism of the complementary protective device 151. Alternatively, the protection engine 206 of the protective device 150 sends a signal to the protection engine 206 of the complementary protective device 151, and the protection engine 206 of the complementary protective device 151 disables the trip mechanism 214 of the complementary protective device 151.

In step 718, a determination is made as to whether the time period has ended. In certain example embodiments, the timer 212 measures the time period and sends a notification to the protection engine 206 that the time period has ended. If the time period has not ended, the process proceeds to step 724. If the time period has ended, then the process proceeds to step 722.

In step 722, the trip mechanism 214 of the protective device 150 and the trip mechanism 214 (or complementary trip mechanism 214) of the complementary protective device 151 is enabled. In certain example embodiments, enabling the trip mechanism 214 of the protective device 150 and/or the complementary protective device 151 allows the trip mechanism 214 to send a trip signal to open a breaker 120, 121 if a fault is detected. Both trip mechanisms 214 can be enabled by the protection engine 206 of the protective device 151. Alternatively, the trip mechanism 214 of the protective device 150 can be enabled by the protection engine 206 of the protective device 150, where the complementary trip mechanism 214 of the complementary protective device 151 can be enabled by the protection engine 206 of the complementary protective device 151 after the protection engine 206 of the complementary protective device 151 receives an enabling signal from the protection engine 206 of the protective device 150.

In any case, because the fault does not originate in the region between the protective device 150 and the complementary protective device 151, or because there is no fault detected by the protection engine 206 during the remainder of the time period after the power spike is detected, the trip mechanisms 214 do not generate and send a trip signal once the trip mechanisms 214 are enabled. After the completion of step 722, the process reverts to step 708. In such a case, subsequent power spikes can cause the method 700 to repeat one or more times. On each occasion that the method 700 repeats, some distinguishing term (e.g., subsequent) can be used to differentiate each time that the method 700 is used to detect a likely fault for a protective device 150, 151.

In step 724, the input signal (unfiltered) is compared with the threshold value during the remainder of the time period. In certain example embodiments, the protection engine 206 compares the input signal with the threshold value during the remainder of the time period. The threshold values can be the same threshold values or different threshold values described above with respect to step 706. In certain example embodiments, the input signal of this step 724 is a raw (unfiltered) signal. In such a case, different but corresponding threshold values can be used in this step 724 relative to the threshold values of step 706. In certain example embodiments, the input signal is the result of a correlation filter (a filter algorithm used by the filter 212), which is a point-on-wave comparison of samples of raw, unfiltered signals and corresponding samples of the filtered signals (as from step 704). In such a case, both data streams are sampled at the same rate.

In step 726, a determination is made as to whether the input signal exceeds a threshold value. In other words, a determination is made as to whether a fault exists. The threshold value can be the same or a different threshold value described above with respect to step 706. The threshold value can be among the thresholds 242 stored in the storage repository 230. The threshold value can be retrieved by the protection engine 206. In certain example embodiments, the protection engine 206 compares the input signal and the threshold value and determines whether the input signal exceeds the threshold value. The threshold value can be a range of values. The threshold value can be a positive value, a negative value, or an absolute value. As an example, the threshold value is exceeded if the input signal is greater than the absolute value of the threshold value. If the input signal exceeds a threshold value, then the protection engine 206 determines whether this portion of the input signal is a power spike.

If the threshold value is a minimum threshold value, then the threshold value is exceeded if the input signal is less than the minimum threshold value. The threshold value can be some multiple (e.g., ten, fifteen) times greater than an average of the input signal prior to the time period. In addition, a certain minimum number of consecutive samples of the input signal may be required to exceed the threshold amount in order for the protection engine 206 to determine that the input signal exceeds the threshold amount (that a fault exists) for purposes of this step 726. For example, if only two consecutive samples are determined to exceed the threshold amount, the protection engine 206 can determine that the input signal does not exceed the threshold value because a minimum of three consecutive samples are required to exceed the threshold value. If the input signal exceeds the threshold value, then the process proceeds to step 727. If the input signal does not exceed the threshold value, the process reverts to step 718.

In step 727, a determination is made as to whether a fault originated in a region between the sensing devices 140, 141 (or, more generically, between the protective devices 150, 151). The fault can be coincidental with the power spike detected in step 706. The determination as to whether the fault originates in a region between the sensing devices 140, 141 is made by the protection engine 206. The protection engine 206 can use the protective device 150 and/or the complementary protective device 151 to determine whether the fault originates in a region between the sensing devices 140, 141. The determination can be made by comparing the polarity of one signal with the polarity of another signal.

For example, the protection engine 206 can compare a polarity of the input signal generated by the sensing device 140 and received by the protective device 150 with a polarity of a complementary input signal generated by the sensing device 141 and received by the complementary protective device 151. In such a case, the fault originates in a region between the sensing device 140 and the complementary sensing device 141 when the polarity of the two input signals is substantially the same (are in phase). Alternatively, the fault originates outside the region between the sensing device 140 and the complementary sensing device 141 when the polarity of the two input signals is substantially the opposite (are out of phase). If the fault originates in the region between the sensing devices 140, 141, then the process proceeds to step 728. If the fault originates outside the region between the sensing devices 140, 141, then the process reverts to step 718.

In step 728, the trip mechanism 214 of the protective device 150 and the trip mechanism 214 (or complementary trip mechanism 214) of the complementary protective device 151 is enabled. This step 728 is substantially similar to step 722 described above. However, in this case, because a fault is detected, and because the fault originates in the region between the sensing device 140 and the complementary sensing device 141, the trip mechanism 214, once enabled by the protection engine 206, is likely to send a trip signal to open a breaker 120, 121. After step 728 is complete, the method 700 ends at the END step.

FIG. 8 illustrates one embodiment of a computing device 800 capable of implementing one or more of the various techniques described herein, and which may be representative, in whole or in part, of the elements described herein. Computing device 800 is only one example of a computing device and is not intended to suggest any limitation as to scope of use or functionality of the computing device and/or its possible architectures. Neither should computing device 800 be interpreted as having any dependency or requirement relating to any one or combination of components illustrated in the example computing device 800. As shown in FIG. 8, the bus 808 is operatively coupled to each of the processing unit(s) 802, the I/O device(s) 806, and the memory/storage component 804.

Computing device 800 includes one or more processors or processing units 802, one or more memory/storage components 804, one or more input/output (I/O) devices 806, and a bus 808 that allows the various components and devices to communicate with one another. Bus 808 represents one or more of any of several types of bus structures, including a memory bus or memory controller, a peripheral bus, an accelerated graphics port, and a processor or local bus using any of a variety of bus architectures. Bus 808 can include wired and/or wireless buses.

Memory/storage component 804 represents one or more computer storage media. Memory/storage component 804 may include volatile media (such as random access memory (RAM)) and/or nonvolatile media (such as read only memory (ROM), flash memory, optical disks, magnetic disks, and so forth). Memory/storage component 804 can include fixed media (e.g., RAM, ROM, a fixed hard drive, etc.) as well as removable media (e.g., a Flash memory drive, a removable hard drive, an optical disk, and so forth).

One or more I/O devices 806 allow a customer, utility, or other user to enter commands and information to computing device 800, and also allow information to be presented to the customer, utility, or other user and/or other components or devices. Examples of input devices include, but are not limited to, a keyboard, a cursor control device (e.g., a mouse), a microphone, and a scanner. Examples of output devices include, but are not limited to, a display device (e.g., a monitor or projector), speakers, a printer, and a network card.

Various techniques may be described herein in the general context of software or program modules. Generally, software includes routines, programs, objects, components, data structures, and so forth that perform particular tasks or implement particular abstract data types. An implementation of these modules and techniques may be stored on or transmitted across some form of computer readable media. Computer readable media may be any available non-transitory medium or non-transitory media that can be accessed by a computing device. By way of example, and not limitation, computer readable media may comprise “computer storage media”.

“Computer storage media” and “computer readable medium” include volatile and non-volatile, removable and non-removable media implemented in any method or technology for storage of information such as computer readable instructions, data structures, program modules, or other data. Computer storage media include, but are not limited to, computer recordable media such as RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computer.

The computer device 800 may be connected to a network (not shown) (e.g., a local area network (LAN), a wide area network (WAN) such as the Internet, or any other similar type of network) via a network interface connection (not shown). Those skilled in the art will appreciate that many different types of computer systems exist (e.g., desktop computer, a laptop computer, a personal media device, a mobile device, such as a cell phone or personal digital assistant, or any other computing system capable of executing computer readable instructions), and the aforementioned input and output means may take other forms, now known or later developed. Generally speaking, the computer system 800 includes at least the minimal processing, input, and/or output means necessary to practice one or more embodiments.

Further, those skilled in the art will appreciate that one or more elements of the aforementioned computer device 800 may be located at a remote location and connected to the other elements over a network. Further, one or more example embodiments may be implemented on a distributed system having a plurality of nodes, where each portion of the implementation (e.g., protection engine 206, hardware processor 220) may be located on a different node within the distributed system. In one or more embodiments, the node corresponds to a computer system. Alternatively, the node may correspond to a processor with associated physical memory. The node may alternatively correspond to a processor with shared memory and/or resources.

The following description (in conjunction with FIGS. 1 through 8) describes a few examples in accordance with one or more example embodiments. The examples are for mitigating the effect of a power spike on a protective device. Terminology used in FIGS. 1 through 8 is used in the provided example without further reference to FIGS. 1 through 8.

### Example 1

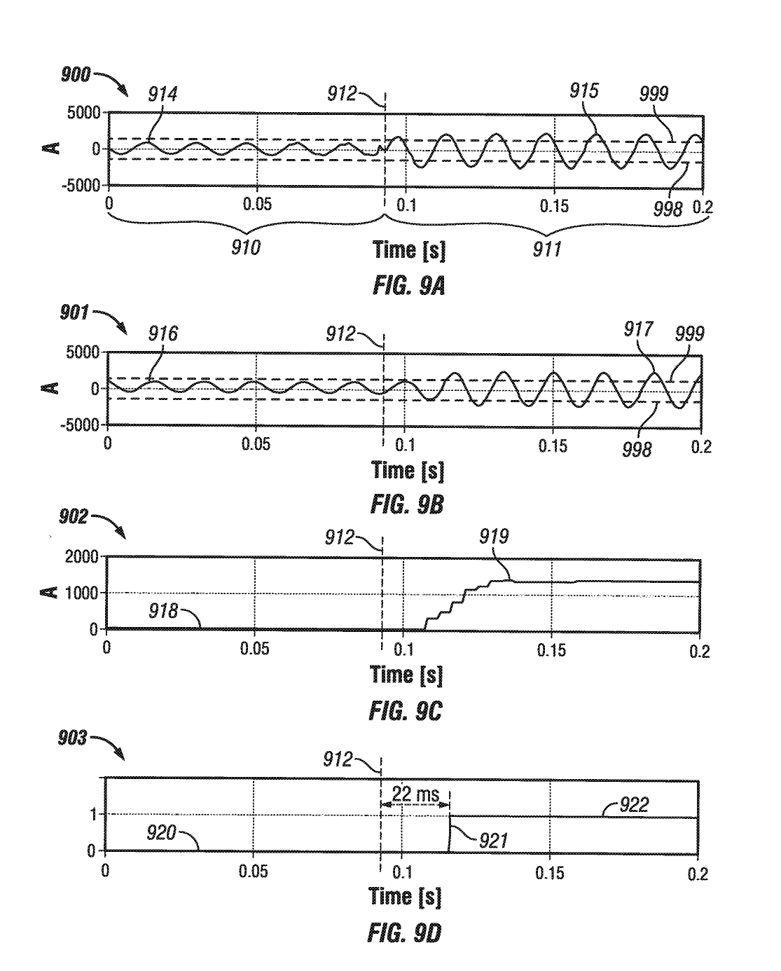

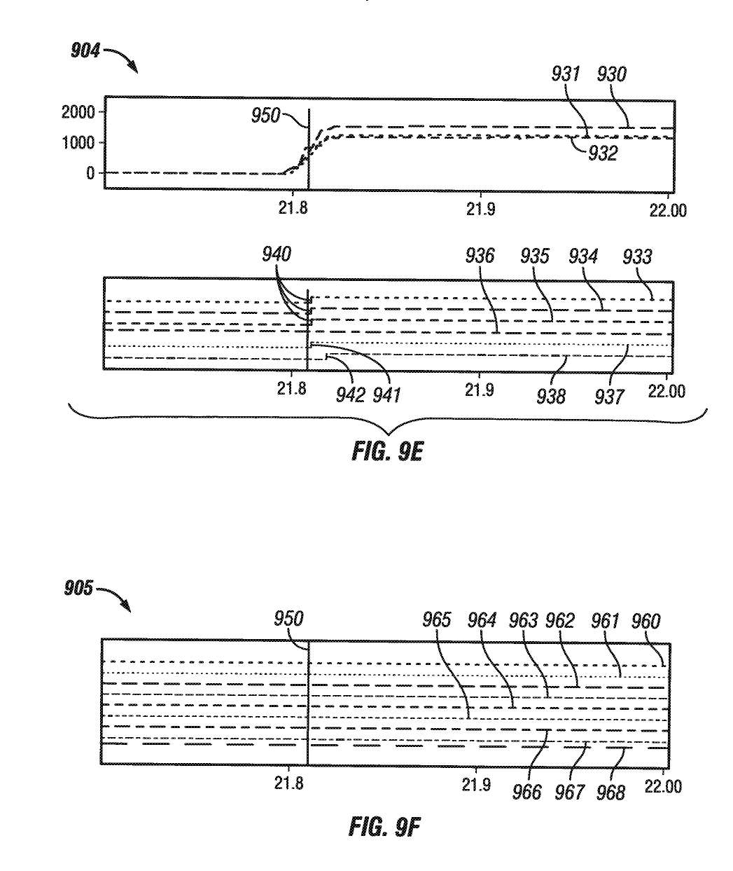

Consider the following example, shown in FIGS. 9A through 9F, which describes detecting a likely fault for a protective device in accordance with one or more example embodiments described above. FIG. 9A shows a graph 900 of the raw (unfiltered) signal 914 (which may also be a signal that has undergone an analog filtering) received by a protective device 150 from a sensing device 140. During time period 910, the raw (unfiltered) input signal 914 is a substantially consistent sine wave centered around zero amps and having peaks that are less than the threshold values 998, 999. At time 912, there is no spike, but a fault begins. As a result, during time period 911, the input signal 915 is a substantially consistent sine wave centered around zero amps, but the peaks exceed the threshold values 998, 999.

FIG. 9B shows a graph 901 of a filtered input signal, which is a filtered version of the input signal from FIG. 9A above. During time period 910, the filtered input signal 916 is a substantially consistent sine wave centered around zero amps and having peaks that are less than the threshold values 998, 999. At time 912, there is no spike, but a fault begins. As a result, during time period 911, the input signal 917 quickly grows to a substantially consistent sine wave centered around zero amps, but the peaks exceed the threshold values 998, 999.

FIG. 9C shows a graph 902 of the operating current of the protective device 150. Prior to and shortly after the fault at time 912, the operating current 918 of the protective device 150 is approximately zero. As the fault stabilizes, the operating current 919 of the protective device 150 grows to approximately 1.3 kA. FIG. 9D shows a graph 903 of the relay status. Up to and shortly after the start of the fault at time 912, the relay is off 920 (has a logic value of zero). Approximately 22 ms after the fault at time 912 begins, the relay transitions 921 and turns on 922 (has a logic value of one). In short, because there was no spike, the protective device 150 operated as it normally does, and example embodiments are not activated and used to detect a likely fault for the protective device 150.

FIGS. 9E and 9F show additional graphs of what was described above with respect to FIGS. 9A-D. FIG. 9E shows a graph 904 of the operating currents 930-932 for each of the three phases for a three-phase fault. These operating currents 930-932 are substantially the same prior to, during, and after the fault 950. Also shown are the states of the differential elements 933-935. Again, the three differential elements 933-935 are all picked up at substantially the same time shortly after the fault 950 begins. Also shown in FIG. 9E is a depiction of the status of the trip mechanism 214. In this case, the status of the trip mechanism 214 is always enabled 936. When the three differential elements 933-935 are all picked up at time 940, the trip mechanism 214 of the protection device 150 is activated, which means that a trip 937 is initiated at time 941, which substantially coincides with time 940. Shortly thereafter, the trip mechanism 214 of the complementary protective device 151 is activated 938 at time 942. In this case, the trip mechanism 214 of the complementary protective device 151 is activated by the protection engine 206 of the protective device 150.

FIG. 9F shows a graph 905 of the states of elements for detecting a likely fault according to certain example embodiments. Line 960 represents spike detection for the A phase, according to certain example embodiments. Line 962 and line 964 represent spike detection for the B and C phase, respectively. Line 961 represents fault-likely detection, according to certain example embodiments. Line 963 and line 965 represent fault-likely detection for the B and C phase, respectively. Line 966 represents the residual value (the vector sum of the phase currents) for the spike detection read by the protective device 150, and line 967 represents the residual value for the fault detection read by the protective device 150. Finally, line 968 represents whether the trip mechanism 214 is enabled or disabled. In this case, the trip mechanism 214 is always enabled (line 968 has a logic value of one), and there is no spike detection. Consequently, because there is no spike detection, there is no fault-likely detection using certain example embodiments.

### Example 2

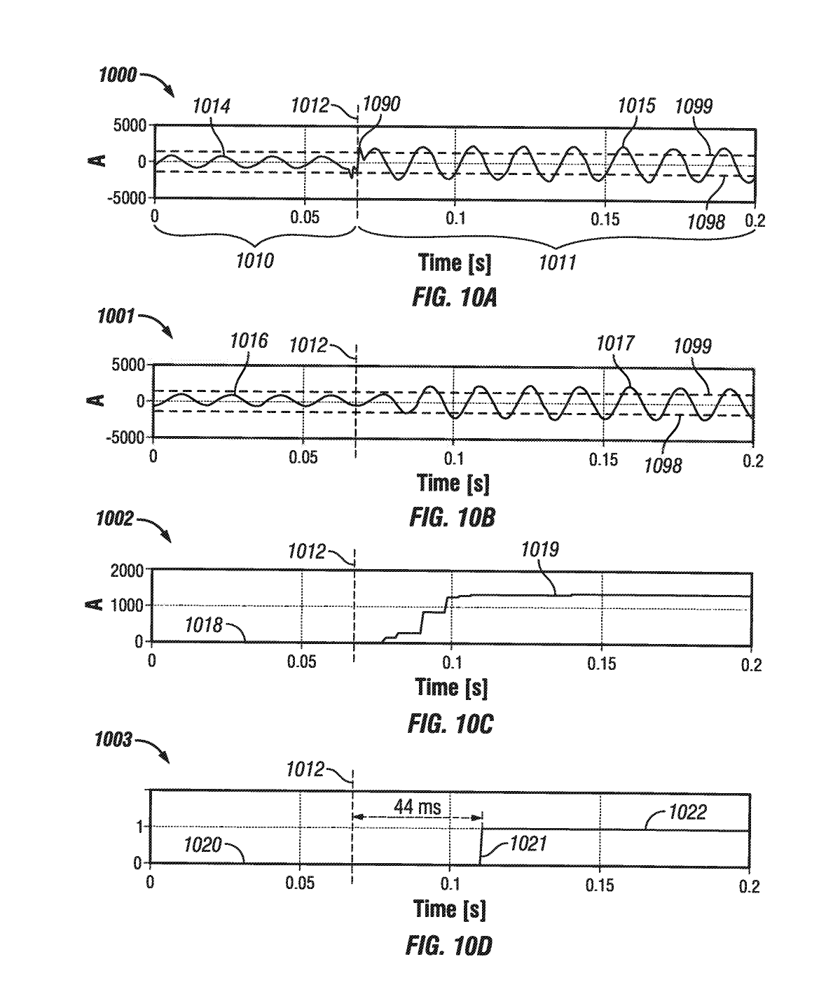

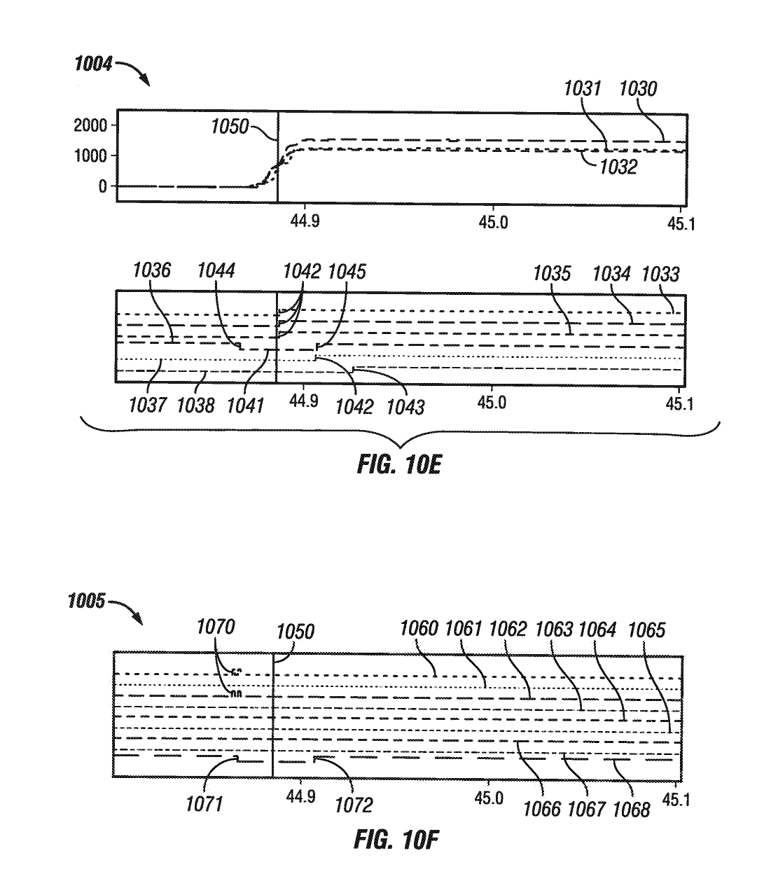

Consider another example, shown in FIGS. 10A through 10F, which describes detecting a spike by an example protective device with the fault-likely function disabled or by a protective device currently known in the art. As a result of not having the fault-likely function available in this example, there is a delay in generating and sending a trip signal for a legitimate fault condition. The graphs in FIGS. 10A-F are substantially similar to the graphs described above with respect to FIGS. 9A-F. Specifically, FIG. 10A shows a graph 1000 of the raw (unfiltered) signal 1014 (which may also be a signal that has undergone an analog filtering) received by a protective device 150 from a sensing device 140. During time period 1010, the raw (unfiltered) input signal 1014 is a substantially consistent sine wave centered around zero amps and having peaks that are less than the threshold values 1098, 1099. At time 1012, there is a power spike 1090, and a fault begins. As a result, during time period 1011, the input signal 1015 is a substantially consistent sine wave centered around zero amps, but the peaks exceed the threshold values 1098, 1099.

FIG. 10B shows a graph 1001 of a filtered input signal, which is a filtered version of the input signal from FIG. 10A above. During time period 1010, the filtered input signal 1016 is a substantially consistent sine wave centered around zero amps and having peaks that are less than the threshold values 1098, 1099. At time 1012, there is a power spike 1090, and a fault begins. As a result, during time period 1011, the input signal 1017 quickly grows to a substantially consistent sine wave centered around zero amps, but the peaks exceed the threshold values 1098, 1099.

FIG. 10C shows a graph 1002 of the operating current of the protective device 150. Prior to and shortly after the spike 1090 and subsequent fault, the operating current 1018 of the protective device 150 is approximately zero. As the fault stabilizes, the operating current 1019 of the protective device 150 grows to approximately 1.3 kA. FIG. 10D shows a graph 1003 of the relay status. Up to and shortly after the start of the spike 1090 and subsequent fault, the relay is off 1020 (has a logic value of zero). Approximately 44 ms after the fault 1012 begins, the relay transitions 1021 and turns on 1022 (has a logic value of one).

FIGS. 10E and 10F show additional graphs of what was described above with respect to FIGS. 10A-D. FIG. 10E shows a graph 1004 of the operating currents 1030-1032 for each of the three phases for a three-phase fault. These operating currents 1030-1032 are substantially the same prior to, during, and after the fault 1050. Also shown are the states of the differential elements 1033-1035. Again, the three differential elements 1033-1035 are all picked up at substantially the same time shortly after the fault 1050 begins. Also shown in FIG. 10E is a depiction of the status 1036 of the trip mechanism 214. In this case, the status 1036 of the trip mechanism 214 is enabled until the power spike 1044, at which time 1041 the trip mechanism is disabled by the protection engine 206.

At time 1045, when the time period expires, the protection engine 206 determines that there is no fault likely condition (because the feature is disabled or otherwise not available), and the trip mechanism 214 is again enabled. The three differential elements 1033-1035 are all picked up during the time period at time 1040. However, since the trip mechanism 214 of the protection device 150 is deactivated during time 1040, the trip 1037 is not initiated until time 1042, which substantially coincides with time 1045 when the timer period ends and the trip mechanism 214 of the protection device 150 is again enabled 1036. Shortly thereafter, at time 1043, the trip mechanism 214 of the complementary protective device 151 is activated 1038. In this case, the trip mechanism 214 of the complementary protective device 151 can be activated by the protection engine 206 of the complementary protective device 151, which received an activation signal from the protection engine 206 of the protective device 150.

FIG. 10F shows a graph 1005 of the states of elements for detecting a likely fault according to certain example embodiments. Line 1060 represents spike detection for the A phase, according to certain example embodiments. Line 1062 and line 1064 represent spike detection for the B and C phase, respectively. Line 1061 represents fault-likely detection, according to certain example embodiments. Line 1063 and line 1065 represent fault-likely detection for the B and C phase, respectively. Line 1066 represents the residual value (the vector sum of the phase currents) for spike detection read by the protective device 150, and line 1067 represents the residual value for fault detection read by the protective device 150. Finally, line 1068 represents whether the trip mechanism 214 is enabled or disabled.

In this case, line 1060 and line 1062 shows spikes detected on the A phase and B phase, respectively, at time 1070. Shortly thereafter, at time 1071, line 1068 shows that the trip mechanism 214 of the protective device 150 goes from enabled to disabled. However, because the fault-likely function is disabled or otherwise unavailable, the detection of the spikes triggers a longer delay than would exist if the example fault-likely function is enabled. Because no further spikes are detected in any of the phases (no change to lines 1061, 1063, or 1065) during the time period, when the time period expires at time 1072, line 1068 shows that the trip mechanism 214 of the protective device 150 goes from disabled to enabled. Thus, because a power spike was detected but there was no fault-likely condition detected using example embodiments described herein, the activation of the trip mechanism 214 of the protective device 150 is delayed an additional 22 ms (for a total of 44 ms).

### Example 3

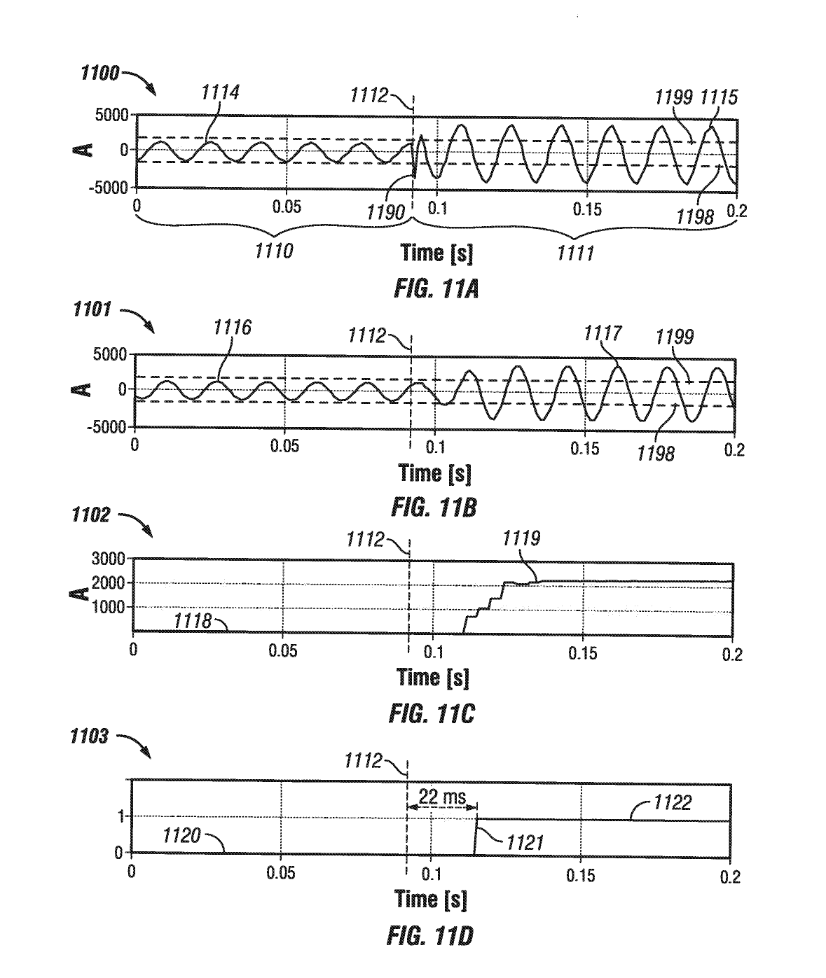

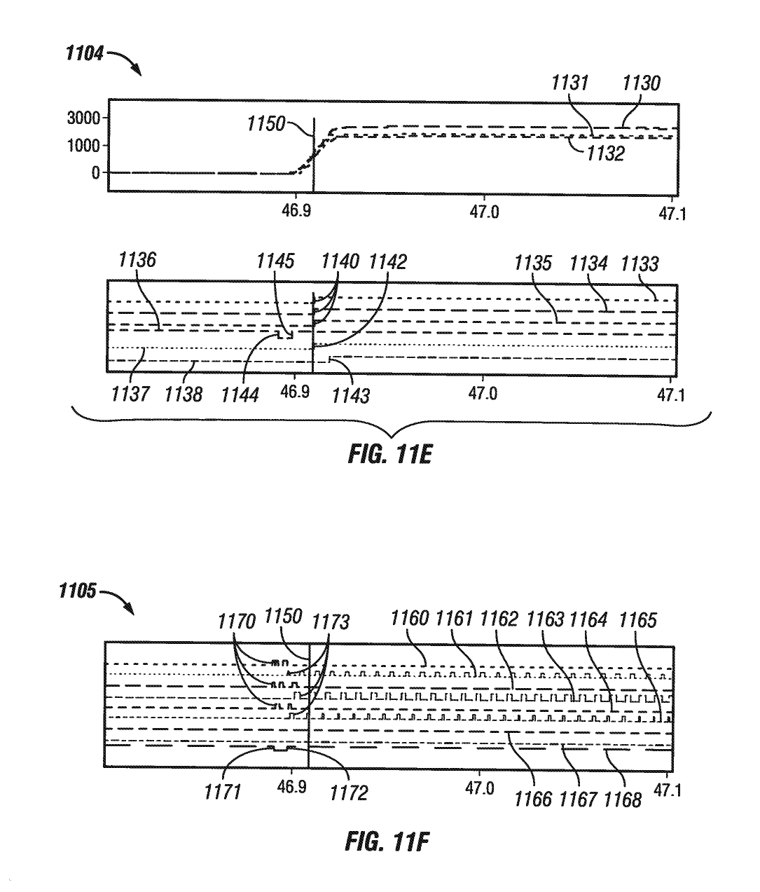

Consider another example, shown in FIGS. 11A through 11F, which describes detecting a likely fault for a protective device in accordance with one or more example embodiments described above. The graphs in FIGS. 11A-F are substantially similar to the graphs described above with respect to FIGS. 10A-F. Specifically, FIG. 11A shows a graph 1100 of the raw (unfiltered) signal 1114 (which may also be a signal that has undergone an analog filtering) received by a protective device 150 from a sensing device 140. During time period 1110, the raw (unfiltered) input signal 1114 is a substantially consistent sine wave centered around zero amps and having peaks that are less than the threshold values 1198, 1199. At time 1112, there is a power spike 1190, and a fault begins. As a result, during time period 1111, the input signal 1115 is a substantially consistent sine wave centered around zero amps, but the peaks exceed the threshold values 1198, 1199.

FIG. 11B shows a graph 1101 of a filtered input signal, which is a filtered version of the input signal from FIG. 11A above. During time period 1110, the filtered input signal 1116 is a substantially consistent sine wave centered around zero amps and having peaks that are less than the threshold values 1198, 1199. At time 1112, there is a power spike 1190, and a fault begins. As a result, during time period 1111, the input signal 1117 quickly grows to a substantially consistent sine wave centered around zero amps, but the peaks exceed the threshold values 1198, 1199.

FIG. 11C shows a graph 1102 of the operating current of the protective device 150. Prior to and shortly after the spike 1190 and subsequent fault, the operating current 1118 of the protective device 150 is approximately zero. As the fault stabilizes, the operating current 1119 of the protective device 150 grows to approximately 2 kA. FIG. 11D shows a graph 1103 of the relay status. Up to and shortly after the start of the spike 1190 and subsequent fault, the relay is off 1120 (has a logic value of zero). Approximately 22 ms after the fault 1112 begins, the relay transitions 1121 and turns on 1122 (has a logic value of one). In short, because there was a power spike 1190, the protective device 150 uses an example embodiment of detecting a likely fault for the protective device 150.

FIGS. 11E and 11F show additional graphs of what was described above with respect to FIGS. 11A-D. FIG. 11E shows a graph 1104 of the operating currents 1130-1132 for each of the three phases for a three-phase fault. These operating currents 1130-1132 are substantially the same prior to, during, and after the fault 1150. Also shown are the states of the differential elements 1133-1135. Again, the three differential elements 1133-1135 are all picked up at substantially the same time shortly after the fault 1150 begins. Also shown in FIG. 11E is a depiction of the status 1136 of the trip mechanism 214. In this case, the status 1136 of the trip mechanism 214 is enabled until the power spike, at which time 1141 the trip mechanism is disabled by the protection engine 206.

At time 1145, before the time period expires, the protection engine 206 determines that there is a fault likely condition, and the trip mechanism 214 is again enabled at time 1145. The protection engine 206 may have determined that there is a fault likely condition because, for example, the power spike originated within the region between the sensing device 140 and the complementary sensing device 141 and the unfiltered input signal exceeds a threshold value during the time period. The three differential elements 1133-1135 are all picked up at time 1140, after the trip mechanism 214 of the protective device 150 is again enabled at time 1145. As a result, the trip mechanism 214 of the protection device 150 is activated during time 1142, which is shortly after the fault at time 1150. Shortly thereafter, at time 1143, the trip mechanism 214 of the complementary protective device 151 is activated, as shown by line 1038. In this case, the trip mechanism 214 of the complementary protective device 151 can be activated by the protection engine 206 of the complementary protective device 151, which received an activation signal from the protection engine 206 of the protective device 150.

FIG. 11F shows a graph 1105 of the states of elements for detecting a likely fault according to certain example embodiments. Line 1160 represents spike detection for the A phase, according to certain example embodiments. Line 1162 and line 1164 represent spike detection for the B and C phase, respectively. Line 1161 represents fault-likely detection, according to certain example embodiments. Line 1163 and line 1165 represent fault-likely detection for the B and C phase, respectively. Line 1166 represents the residual value (the vector sum of the phase currents) for spike detection read by the protective device 150, and line 1167 represents the residual value for fault detection read by the protective device 150. Finally, line 1168 represents whether the trip mechanism 214 is enabled or disabled.

In this case, line 1160, line 1162, and line 1164 each show spikes detected on the A phase, B phase, and C phase, respectively, at approximately time 1170. Shortly thereafter, at time 1171, line 1168 shows that the trip mechanism 214 of the protective device 150 goes from enabled to disabled. Shortly thereafter, at approximately time 1173, the protection engine 206 determines that there is a likely fault on the A phase, B phase, and C phase, as shown by the steps in line 1161, line 1162, and line 1163, respectively. Since the fault likely condition exists before the time period expires, the protection engine 206 enables the trip mechanism 214 of the protective device 150 at time 1172, as shown by line 1168. Thus, because a power spike was detected and there is a fault-likely condition detected using example embodiments described herein, the activation of the trip mechanism 214 of the protective device 150 occurs immediately when the fault is detected at time 1150, which results in the default delay of 22 ms.

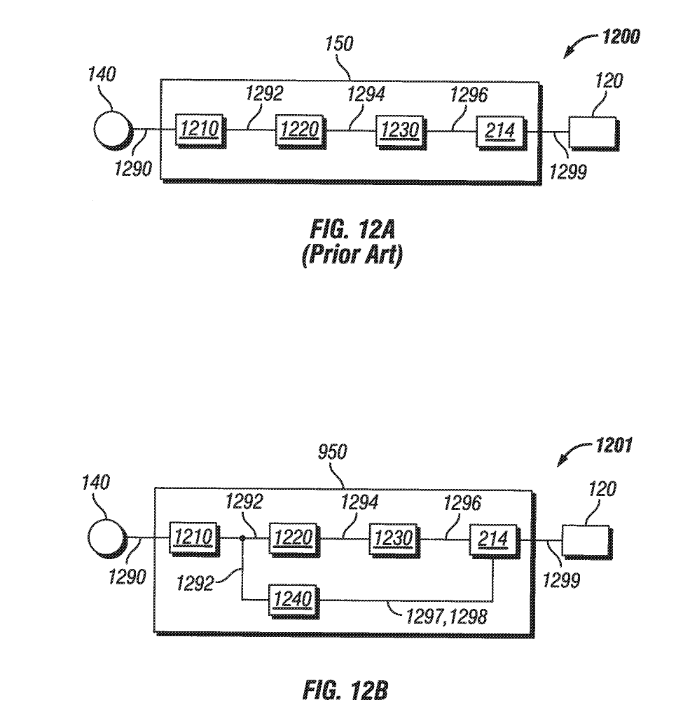

FIG. 12A shows an example schematic flow diagram 1200 of an input signal through a protective device 150 without the use of certain example embodiments. FIG. 12B shows an example schematic flow diagram 1201 of an input signal through a protective device 950 using certain example embodiments. Referring to FIGS. 1, 2, 12A, and 12B, without using certain example embodiments, a raw input signal 1290 is produced by a sensing device 140 and sent to an analog filter 1210 in a protective device 150. After being processed by the analog filter 1210, the raw input signal 1290 becomes an input signal 1292, which proceeds to a digital filter 1220 in the protective device 150. After being processed by the digital filter 1220, the input signal 1292 becomes a filtered signal 1294 and is sent to a protection engine 1230, which may be the same or different than the protection engine 206 of FIG. 2. The protection engine 1230 then sends data 1296 to the trip mechanism 214, which is always enabled and uses the data 1296 to determine whether a trip signal 1299 is generated and sent to a breaker 120.

In FIG. 12B, using example embodiments, a parallel process is added. Specifically, the input signal 1292 (or, in some cases, the raw input signal 1290) is received by the protective device 950 and copied. The original (or a copy of the) input signal 1292 continues as described above in FIG. 12A. The copy of the (or the original) input signal 1292 is sent to an example embodiment 1240, which includes the protection engine 206 and the correlation filter 210. The example embodiment 1240 receives the input signal 1292 and performs the steps described above. Specifically, the example embodiment 1240 detects a power spike in the input signal 1292, sends a signal 1298 to disable the trip mechanisms 214, starts to measure a time period. During the time period, the example embodiment 1240 determines whether a fault condition exists in the input signal 1292 and, if so, whether the fault condition originates in a certain region. If so, then the example embodiment 1240 sends a signal 1297 to enable the trip mechanism 214. If not, then the example embodiment 1240 keeps analyzing the input signal 1292 until the time period ends, at which time the example embodiment 1240 sends a signal 1297 to enable the trip mechanism 214.

Example embodiments provide for detecting a likely fault for a protective device. Specifically, example embodiments provide for, when a power spike is detected in an input signal, disabling a trip mechanism of a protective device for a minimal amount of time. During this minimal amount of time, example embodiments determine whether a fault condition exists and, if so, where the fault condition originates. If a fault condition exists and originates in a certain region, then example embodiments enable the trip mechanism. Example embodiments allow such a determination to occur without delaying so long as to jeopardize assets within a system when a legitimate fault condition exists.

Example embodiments allow for a reduction in down time by reducing the occurrences of a trip mechanism sending a trip signal to a breaker in response to mere power spikes caused by normal operating conditions (e.g., operating a breaker) and/or extraneous events (e.g., lighting strike) that are commonly interpreted by protective devices as requiring actuation of a trip mechanism. Thus, example embodiments save in lost opportunity costs, as well as unnecessary maintenance and operations costs.

Although embodiments described herein are made with reference to example embodiments, it should be appreciated by those skilled in the art that various modifications are well within the scope and spirit of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A method for detecting a fault for a protective device, the method comprising:
receiving an input signal;
detecting a power spike;
upon detecting the power spike:
disabling a trip mechanism;
disabling a complementary trip mechanism of a complementary protective device; and
starting a time period; and
during a remainder of the time period:
determining, using the complementary protective device, whether the fault originates between a sensing device and a complementary sensing device; and
determining whether the input signal exceeds the threshold value.

2. The method of claim 1, further comprising:
determining, during the time period, that the input signal is less than the threshold value during the remainder of the time period; and
when the remainder of the time period ends:
enabling the trip mechanism of the protective device; and
enabling the complementary trip mechanism of the complementary protective device,
wherein the trip mechanism and the complementary trip mechanism remain deactivated after being enabled.

3. The method of claim 2, further comprising:
detecting, at a time after the time period, a subsequent power spike;
upon detecting the subsequent power spike:
disabling the trip mechanism;
disabling the complementary trip mechanism of the complementary protective device; and
starting a subsequent time period; and
during a remainder of the subsequent time period:
determining, using the complementary protective device, whether a subsequent fault originates between the sensing device and the complementary sensing device; and
determining whether the input signal exceeds the threshold value during the remainder of the subsequent time period.

4. The method of claim 1, further comprising:
determining that the input signal exceeds the threshold value during the remainder of the time period;
determining that the fault originates between the sensing device and the complementary sensing device; and
in response to determining that the input signal exceeds the threshold value and determining that the fault originates between the sensing device and the complementary sensing device:
enabling the trip mechanism; and
enabling the complementary trip mechanism,
wherein the trip mechanism and the complementary trip mechanism are activated after being enabled.

5. The method of claim 4, wherein determining that the input signal exceeds the threshold value comprises determining that a number of consecutive samples of the input signal exceeds the threshold value.

6. The method of claim 1, further comprising:
determining, during the remainder of the time period, that the fault originates outside a region between the sensing device and the complementary sensing device; and
enabling, in response to determining that the fault originates outside the region between the sensing device and the complementary sensing device, the trip mechanism and the complementary trip mechanism,
wherein the trip mechanism and the complementary trip mechanism remain deactivated after being enabled.

7. The method of claim 1, wherein determining whether the fault originates between the sensing device and the complementary sensing device comprises comparing a first polarity of the input signal received by the protective device and a second polarity of a complementary input signal received by the complementary protective device, wherein the fault originates in a region between the sensing device and the complementary sensing device when the first polarity has a polarity substantially similar to the polarity of the second polarity, and wherein the fault originates outside the region between the sensing device and the complementary sensing device when the first polarity is substantially opposite the second polarity.

8. The method of claim 1, wherein the time period is no more than 3 cycles.

9. The method of claim 1, wherein the complementary trip mechanism of the complementary protective device is disabled by the protective device.

10. The method of claim 1, wherein receiving the input signal comprises:
receiving a plurality of unfiltered signals.

11. The method of claim 1, wherein starting the time period is performed using a hardware processor.

12. The method of claim 1, wherein the threshold value is approximately a number times an average of the input signal prior to the time period.

13. A protective device, comprising:
memory for storing a plurality of instructions;
a hardware processor communicably coupled to the memory, wherein the hardware processor executes the plurality of instructions stored in the memory;
a trip mechanism that sends a trip signal to a breaker;
a correlation filter that detects a power spike in an input signal;
a timer that measures a time period; and
a protection engine communicably coupled to the timer, a first sensing device, a second sensing device, the trip mechanism, the correlation filter, and the hardware processor, wherein the protection engine:
receives the input signal generated by the first sensing device;
upon detection of the power spike:
disables the trip mechanism;
disables a complimentary trip mechanism of a complementary protective device; and
instructs the timer to start measuring the time period; and
during a remainder of the time period:
determines, using the complementary protective device, whether a fault originates between the sensing device and the complementary sensing device; and
determines whether the input signal exceeds the threshold value,
wherein the protection engine enables and activates the trip mechanism and the complementary trip mechanism when the input signal exceeds the threshold value during the remainder of the time period.

14. The protective device of claim 13, wherein the first sensing device comprises a Rogowski coil.

15. The protective device of claim 13, further comprising:
a comparator communicably coupled to the protection engine, wherein the comparator:
receives the first signal generated by the first sensing device and a second signal generated by a second sensing device; and
generates the input signal, wherein the input signal is an unfiltered signal.

16. The protective device of claim 13, wherein the second signal is received from the complementary protective device.

17. A protective device system, comprising:
at least one electrical component;
a first sensing device coupled to a first conductor, wherein the first sensing device generates an input signal based on power flowing through the first conductor; and
a protective device communicably coupled to the first sensing device and the second sensing device, wherein the protective device comprises:
memory for storing a plurality of instructions;
a hardware processor communicably coupled to the memory, wherein the hardware processor executes the plurality of instructions stored in the memory;
a trip mechanism that sends a trip signal to a the at least one electrical component;
a correlation filter that detects a power spike in the input signal;
a timer that measures a time period;
a protection engine communicably coupled to the timer, the first sensing device, and the hardware processor, wherein the protection engine:
receives the input signal generated by the first sensing device;
upon detection the power spike:
disables the trip mechanism;
disables a complementary trip mechanism of a complementary protective device; and
instructs the timer to start measuring the time period; and
during a remainder of the time period:
determines, using the complementary protective device, whether a fault originates between the sensing device and the complementary sensing device; and
determines whether the input signal exceeds the threshold value.

18. The protective device system of claim 17, wherein the at least one electrical component is a circuit breaker electrically coupled to the first sensing device and a power source, wherein the first sensing device is electrically disposed between the circuit breaker and the protective device.

19. The protective device system of claim 18, wherein the trip mechanism sends the tip signal to open the circuit breaker when the trip mechanism is enabled by the protection device, wherein the protection device enables the trip mechanism when the protection device determines, during the remainder of the time period, that the fault originates between the sensing device and the complementary sensing device and that the input signal exceeds the threshold value.

20. The protective device system of claim 17, further comprising a second sensing device coupled to the first conductor and a complementary protective device, wherein the second sensing device generates an additional signal based on the power flowing through the first conductor, wherein the complementary protective device is communicably coupled to the protective device, the first sensing device, and a second sensing device, wherein the at least one electrical component, the protective device and the complementary protective device are communicably coupled using a fiber optic technology.
